(19) United States
(12) Patent Application Publication
(10) Pub. No.: US 2024/0093403 A1
(43) Pub. Date: Mar. 21, 2024

(54) METHOD AND SYSTEM FOR MANUFACTURING AN OPTOELECTRONIC DEVICE AND OPTOELECTRONIC DEVICE MANUFACTURED USING SAME

(71) Applicant: SOCPRA SCIENCES ET GENIE S.E.C., Sherbrooke (CA)

(72) Inventors: Mohammad Reza AZIZIYAN, Sherbrooke (CA); Ionela-roxana ARVINTE, Sherbrooke (CA); Abderraouf BOUCHERIF, Sherbrooke (CA); Richard ARÈS, Sherbrooke (CA)

(21) Appl. No.: 18/264,975

(22) PCT Filed: Feb. 10, 2022
(86) PCT No.: PCT/CA2022/050193

§ 371 Date: Aug. 10, 2023

Related U.S. Application Data
(60) Provisional application No. 63/148,229, filed on Feb. 11, 2021.
(60) Provisional application No. 63/241,572, filed on Sep. 8, 2021.

(51) Int. Cl. C30B 25/20; C30B 25/10; C30B 25/18; C30B 29/08; C30B 33/02

(52) U.S. Cl. CPC C30B 25/20; C30B 25/10; C30B 25/186; C30B 29/08; C30B 33/02

(57) ABSTRACT

There is described a method of manufacturing an optoelectronic device. The method generally has: etching a wafer of monocrystalline germanium, said etching forming a given density of pores contained within said monocrystalline germanium, with at least some of said pores being exposed at a surface of said wafer; depositing a substrate layer of a given crystalline material onto said surface, said substrate layer closing exposed ones of said pores; heating said wafer and said substrate layer, said heating transforming said pores into cavity-interspersed pillars interconnected to one another within said wafer; making a semiconductor component integral to said substrate layer, including collectively forming said optoelectronic device; and breaking said cavity-interspersed pillars of said wafer thereby freeing said optoelectronic device from a remaining wafer portion of said wafer.

### FIELD

The improvements generally relate to optoelectronic devices, and more particularly relate to substrates for such optoelectronic devices.

### BACKGROUND

Optoelectronic devices generally have semiconductor components grown on substrates. As the semiconductor components and the substrate are sometimes made of different crystalline materials, the semiconductor's lattice constant is preferably matched to the substrate's lattice constant to avoid undesirable crystalline defects. For instance, semiconductor components based on III-V semiconductors such as InGaAs and GaInNAs are generally grown on bulk germanium substrates, as the lattice constants of germanium and of III-V semiconductors are similar to one another. Although existing bulk germanium substrates used for the manufacture of optoelectronic devices have been found to be satisfactory, there remains room for improvement.

### SUMMARY

It was found that there is a need in the industry to manufacture germanium-based optoelectronic devices without wholly sacrificing a bulk germanium substrate.

In a first aspect, there is provided a method of making a component, said method comprising the steps of: at a first temperature, depositing a first non-porous layer of monocrystalline germanium (Ge) onto a porous layer of a monocrystalline Ge substrate, whereby said first non-porous layer monocrystalline is deposited onto the porous surface layer of said monocrystalline Ge substrate; at a second temperature, depositing a second non-porous layer of monocrystalline Ge onto said first non-porous layer, whereby said second temperature is higher than said first temperature; and separating said first non-porous layer, together with the second non-porous layer, from said porous surface layer of said monocrystalline Ge substrate.

The first non-porous layer monocrystalline can be deposited via epitaxy onto the porous surface layer of said monocrystalline Ge substrate.

In the context of the method according to the first aspect, said first and said second non-porous layer can be separated from said porous layer by inducing mechanical stress, such as by pulling, spalling, etc., or by chemical means (e.g. circulating an acid through the pores of the porous layer).

In the context of the method according to the first aspect, the first non-porous layer of monocrystalline Ge is deposited at a temperature below 400° C., preferably, between 80 and 400° C., more preferably between 200 and 300° C. Most preferably, said first non-porous layer is deposited at a temperature of 220° C., 240° C., 260° C., 280° C. or 300° C., or any temperature there in between.

In the context of the method according to the first aspect, said first non-porous layer can be deposited using a low temperature precursor, preferably digermane. In the context of the present invention, the term “low temperature precursor” is to be understood as a germanium precursor known to the skilled person, which allows for the formation of a non-porous monocrystalline Ge layer via epitaxy at a temperature below 400° C., preferably at a temperature between 80 and 400° C., more preferably between 150 and 350° C., more preferably between 200 and 300° C., and most preferably, at a temperature of about 220° C., 240° C., 260° C., 280° C. or 300° C., or any temperature there in between.

In the context of the method according to the first aspect, the non-porous layer is deposited with a thickness between 10 and 1000 nm, preferably between 10 and 100 nm. Preferably, said first non-porous layer is deposited with a thickness of 20, 30, 40, 50, 60, 70, 80, 90 or 100 nm, or any thickness there in between.

In the context of the method according to the first aspect, the second non-porous layer is deposited at a temperature above 400° C. Preferably, at a temperature between 400° C. and 850° C., between 400° C. and 600° C., between 450 and 550° C., and preferably around 500° C. It is preferred that the difference in temperature for deposition of said first and said second non-porous layer is at least 25° C., more preferably at least 50° C.

In the context of the method according to the first aspect, the second non-porous layer is deposited using a high temperature precursor, preferably germanium tetrachloride (GeCl₄). In the context of the present invention, the term “high temperature precursor” is to be understood as a germanium precursor known to the skilled person, which allows for the formation of a non-porous monocrystalline Ge layer via epitaxy at a temperature above 400° C., preferably between 400° C. and 850° C., preferably between 400° C. and 600° C., more preferably between 450 and 550° C., and most preferably around 500° C.

In the context of the method according to the first aspect, the second non-porous layer can have a thickness between 0.1 and 100 μm, preferably between 0.1 and 10 μm. In another embodiment, the overall thickness of the first layer and of the second layer of non-porous germanium can be between 100 and 600 μm, such as 140 μm, 175 μm, 225 μm or 450 μm.

In a specific aspect, the present invention also provides a germanium wafer obtained according to the process described above. Preferably, said germanium wafer comprises said first and second non-porous layers having a combined thickness of about 140 μm and has a diameter of about 4″; a combined thickness of about 175 μm and has a diameter of about 4″; or a combined thickness of about 225 μm and wherein said wafer has a diameter of about 6″; or a combined thickness of about 450 μm and wherein said wafer has a diameter of about 8″.

In the context of the method according to the first aspect, the second non-porous layer can have a thickness significantly greater than the thickness of the first non-porous layer, preferably at least an order of magnitude greater.

In the context of the method according to the first aspect, the first non-porous layer and the second non-porous layer can be deposited using a different precursor.

In the context of the method according to the first aspect, the method can further include a step of depositing at least one additional layer onto said second non-porous layer. More preferably, wherein said at least one additional layer includes one or more layers of III-V semiconductor crystalline materials and said component is a component of an opto-electrical device. Alternately, the method can be used to produce a kerfless wafer which is sold as such.

In the context of the method according to the first aspect, the method can further include a step of annealing the first non-porous layer and the substrate at a temperature above 400° C., preferably between 400 and 600° C., prior to depositing said second non-porous layer.

In the context of the method according to the first aspect, the first non-porous layer and/or said second non-porous layer are deposited by molecular beam epitaxy (MBE). MBE was found to be of specific interest for the deposition of non-porous layers having a thickness of 10 nm to 1 μm. In another preferred embodiment said first non-porous layer and/or said second non-porous layer are deposited by CVD, such as MOCVD, or any other technique known to the person skilled in the art. CVD and MOCVD were found to be of specific interest for the deposition of non-porous layers having a thickness from 1 μm to 600 μm.

In the context of the method according to the first aspect, the method can further include a step of forming a porous surface layer of monocrystalline germanium (Ge) in a non-porous substrate of monocrystalline germanium prior to depositing said first non-porous layer.

In the context of the method according to the first aspect, said first non-porous layer, together with the second non-porous layer, can be separated from said porous surface layer of said monocrystalline Ge substrate. In one example, the separation/detachment can be performed by applying mechanical stress, such as by pulling the first layer and the second layer away from the substrate either as a whole, or by peeling, which can lead to the yielding of said porous layer to mechanical stress imparted by pulling. In another example, the detachment can involve a chemical reaction with a solution which infiltrates the pores and which dissolves germanium.

In the context of the method according to the first aspect, the method can further include a step of chemical cleaning of the exposed surface of said porous surface layer, prior to depositing said first non-porous layer. Chemical cleaning involves exposing the exposed surface of the porous layer to an etchant/electrolyte for a certain period of time, and the etchant/electrolyte can be in liquid or gaseous form, for example. Preferably, said chemical cleaning includes removal of an oxidation layer of said exposed surface by halogen surface terminations. Indeed, an oxidation layer can have been spontaneously formed due to exposure of the substrate to the oxygen present in the atmosphere. Preferably, said chemical cleaning includes applying a halogen-solvent solution to the exposed surface. More preferably, the halogen-solvent solution has hydrogen bromide.

In the context of the method according to the first aspect, the method can further include performing a low temperature annealing to the substrate subsequently to said chemical cleaning and prior to performing the deposition of the first non-porous layer, the low temperature annealing at a temperature of between 100 and 400° C., preferably between 200 and 300° C. Preferably, the substrate is moved into an oven prior to said low temperature annealing, and the substrate is maintained in the oven during the steps of performing deposition of the first non-porous layer and of performing deposition of the second non-porous layer. The enclosed volume of the furnace can be oxygen free and can also have a reducing atmosphere to avoid exposing the substrate to humidity and oxygen which could lead to deterioration.

In the context of the method according to the first aspect, the method can further include, subsequently to said separation step, forming a new porous layer at the exposed face of the non-porous Ge substrate and repeating said steps of performing deposition of the first and second non-porous layers onto the new porous layer.

Heat treatments steps and preferably also pre-treatment of materials such as germanium substrates, are preferably performed in a furnace in an oxygen- and water-free atmosphere, preferably in vacuum or otherwise in a reducing atmosphere.

In accordance with an aspect of the present disclosure, there is provided a method of manufacturing an optoelectronic device, the method comprising: etching a wafer of monocrystalline germanium using first etching conditions, said etching forming a given density of pores contained within said monocrystalline germanium, with at least some of said pores being exposed at a surface of said wafer; depositing a substrate layer of a given crystalline material onto said surface of said wafer, said substrate layer closing exposed ones of said pores; heating said wafer and said substrate layer to a first temperature for a first period of time within a given environment, said heating transforming said pores into cavity-interspersed pillars interconnected to one another within said wafer; making a semiconductor component integral to said substrate layer, including collectively forming said optoelectronic device; and breaking said cavity-interspersed pillars of said wafer thereby freeing said optoelectronic device from a remaining wafer portion of said wafer.

In accordance with another aspect of the present disclosure, there is provided a system for manufacturing an optoelectronic device, the system comprising: an etching station configured for etching a wafer of monocrystalline germanium using first etching conditions, said etching forming a given density of pores contained within said monocrystalline germanium, with at least some of said pores being exposed at a surface of said wafer; a deposition station configured for depositing a substrate layer of a given crystalline material onto said surface of said wafer, said substrate layer closing exposed ones of said pores; a heating station configured for heating said wafer and said substrate layer to a first temperature for a first period of time within a given environment, said heating transforming said pores into cavity-interspersed pillars interconnected to one another within said wafer; a semiconductor component station configured for making a semiconductor component integral to said substrate layer, including collectively forming said optoelectronic device; and a detachment station configured for breaking said cavity-interspersed pillars of said wafer thereby freeing said optoelectronic device from a remaining wafer portion of said wafer.

In accordance with another aspect of the present disclosure, there is provided a optoelectronic device comprising: a substrate layer made of one or more crystalline materials, the substrate layer having a first surface and a second surface opposite to said first surface, a semiconductor component made integral to said first surface of said substrate layer, said second surface of said substrate layer having a plurality of broken cavity-interspersed pillar portions made of a monocrystalline germanium material and protruding away from the second surface of said substrate layer, wherein said broken cavity-interspersed pillar portions have a dimension ranging from about 20 nm to about 500 nm.

Many further features and combinations thereof concerning the present improvements will appear to those skilled in the art following a reading of the instant disclosure.

### DESCRIPTION OF THE FIGURES

In the figures,

FIG. 1 is an oblique view of an example of an optoelectronic device having a semiconductor component made integral to a substrate layer detached from a wafer of monocrystalline germanium, in accordance with one or more embodiments;

FIGS. 1A to 1D present a microscope image (upper portion) and diameter distribution (lower portion) of surface roughness following detachment in accordance with respective examples of as-grown, with subsequent annealing at 650° C., with subsequent annealing at 700° C. and with subsequent annealing at 750° C., respectively;

FIG. 2A is a side elevation view of an example of a wafer of monocrystalline germanium, in accordance with one or more embodiments;

FIG. 2B is a side elevation view of the wafer of FIG. 1A after an etching step forming a given density of pores contained within the wafer, with at least some of the pores being exposed at a surface thereof, in accordance with one or more embodiments;

FIG. 2C is a side elevation view of the wafer of FIG. 2B after the deposition of a substrate layer of a given crystalline material onto the surface of the wafer, with the substrate layer closing at least some of the exposed pores, in accordance with one or more embodiments;

FIG. 2D is a side elevation view of the wafer of FIG. 2C after a heating step transforming the pores into cavity-interspersed pillars interconnected to one another within the wafer, in accordance with one or more embodiments;

FIG. 2E is a side elevation view of the wafer of FIG. 2D after an electronic component is made integral to the surface of the wafer, the electronic component and the substrate layer collectively forming an electronic device, in accordance with one or more embodiments;

FIG. 2F is a side elevation view of a remaining wafer portion after a detachment step in which the electronic device is detached from the wafer by breaking the cavity-interspersed pillars, in accordance with one or more embodiments;

FIG. 2G is a side elevation view of the remaining wafer portion of FIG. 2F after a surface-processing step in which broken cavity-interspersed pillars protruding from the remaining wafer portion are removed, the remaining wafer portion being usable as a new wafer of monocrystalline germanium for the manufacture of another optoelectronic device, in accordance with one or more embodiments;

FIG. 3 is a schematic view of an example system for manufacturing optoelectronic devices, showing stations communicatively coupled to a controller, in accordance with one or more embodiments;

FIG. 4 is a schematic view of an example of a computing device of the controller of FIG. 3, in accordance with one or more embodiments;

FIG. 5 is a flow chart of an example of a method of manufacturing optoelectronic devices, in accordance with one or more embodiments;

FIG. 6A is a schematic view of an example of an etching station, in accordance with one or more embodiments;

FIG. 6B is a schematic view of an example of a deposition station, in accordance with one or more embodiments;

FIG. 7A is side elevation view of a wafer of monocrystalline germanium after an etching step forming a given density of pores within the wafer, in accordance with one or more embodiments;

FIG. 7B is side elevation view of the etched wafer of FIG. 7A after a deposition step in which a buffer germanium layer is deposited on the etched wafer, in accordance with one or more embodiments;

FIG. 7C is side elevation view of the etched wafer of FIG. 7B after a heating step and a semiconductor component making step, in accordance with one or more embodiments;

FIG. 8 is a graph showing temperature as a function of time as the steps of FIGS. 7A through 7C are performed, in accordance with one or more embodiments.

FIG. 9 is a schematic view of an example of a process flow to obtain a Ge monocrystalline membrane, in which FIG. 9(a) shows formation of single porous Ge layer; FIG. 9(b) shows low temperature sintering and deposition of Ge buffer layer to create a template for the Ge epitaxy; FIG. 9(c) shows high temperature sintering and Ge epitaxial growth to create a separation layer for the detachment; and FIG. 9(d) shows detachment of the Ge NM;

FIG. 10(a) is a photo showing a typical 4-inch Epitaxial Ge grown on PGe/Ge; FIG. 10(b) shows an example AFM tapping-mode image with RMS roughness of 0.48 nm for epitaxial Ge/PGe (taken from the center area); FIG. 10(c) shows a cross-section SEM image of the epitaxial Ge layer; and FIG. 10(d) shows the inset is a zoom into the void layer region;

FIG. 11(a) is a cross-sectional view of a single Ge porous layer with a porosity of 40-45% and with a Ge layer deposited at low temperature; FIG. 11(b) shows the porous layer during the annealing; and FIG. 11(c) shows the porous layer after annealing;

FIG. 12(a) shows an example 2theta scan of homoepitaxial Ge grown on PGe/Ge template (with reference JCPDS card no 04-0545 is shown at bottom), with the inset showing a semilog plot of omega rocking curve from a homoepitaxial Ge compared to the one obtained from a bulk substrate; and FIG. 12(b) shows an example FWHM and intensity variation of Ge(004) as function of off-cut angle;

FIG. 13(a) shows an example grazing incidence x-ray diffraction 2θχ/φ-scan curves for Epi Ge layer at different grazing incidence angles αi from (220) reflection; FIG. 13(b) shows a plot of the FWHM and peak position of rocking curve (220) plane measured by IPGID, with the solid lines are drawn to guide the eye; and FIG. 13(c) shows an example Raman spectra of Epitaxial Ge layer grown on a PGe/Ge substrate, obtained with 632 nm excitation;

FIG. 14(a) shows an example cross section TEM image of the Epilayer Ge structure; FIG. 14(a₁) shows HRTEM of HT Ge, with inset in FIG. (a₁) is the selected-area electron diffraction (SAED) pattern from HT Ge taken along [1 10] zone axis; FIG. 14(a ₂) shows the inverse fast Fourier transform from HT Ge showing only (220) crystalline planes; FIG. 14(b₁) shows a HRTEM from Ge bulk, FIG. 14(b₁) is the SAED pattern from Ge bulk; and FIG. 14(b₂) shows the inverse fast Fourier transform from Ge bulk displaying only (220) crystalline planes; and

FIG. 15(a) shows a schematic view an adhesion test; FIG. 15(b) shows a low magnification top view SEM on Ge NM, with the inset showing a zoom on the pillars distribution; FIG. 15(c) shows an AFM image showing the Ge NM morphology on the stainless, with the RMS roughness being about 6 nm; and FIG. 15(d) shows an example 2theta scan of epi-Ge before release (on PGe/Ge bulk) and Ge NM on stainless steel.

### DETAILED DESCRIPTION

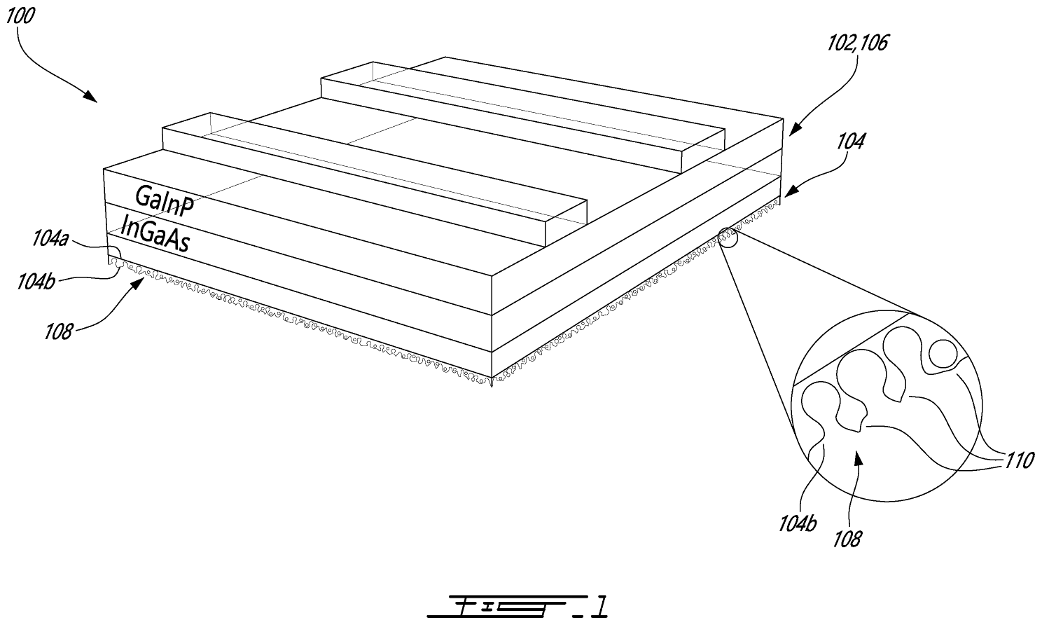

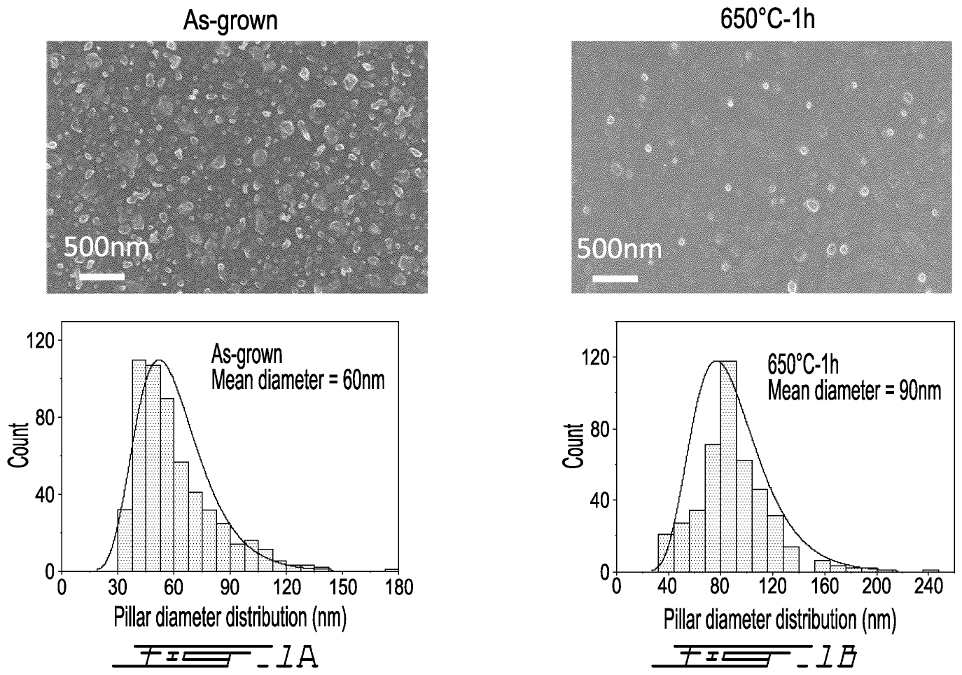

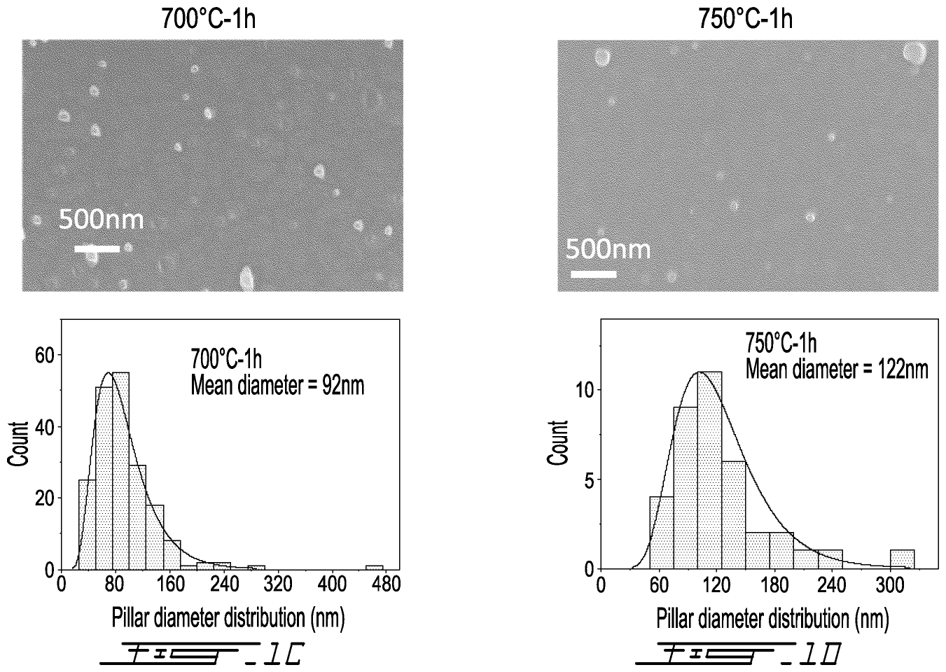

FIG. 1 is an oblique view of an example optoelectronic device 100 having a semiconductor component 102 on a substrate layer 104. Examples of such a semiconductor component 102 can include photodiodes, solar cells, phototransistors, photomultipliers, optoisolators, integrated optical circuit elements, photoresistors, charge-coupled imaging devices, laser diodes, quantum cascade lasers, light-emitting diodes, organic light emitting diodes, photoemissive camera tubes, transducers, thermophovoltaics, and quantum devices, to name some examples. A semiconductor component can include Silicon-based group IV heterostructures (e.g., Ge/Si, GeSn/Si, SiGeSn/Si, SiC/Si, etc.), III-V heterostructures on Silicon such as Gallium Nitride on Silicon (GaN/Si), Aluminum nitride on Silicon (AlN/Si), Gallium Arsenide on Si (GaAs/Si), Gallium Phosphide on Si (GaP/Si), Indium Gallium Arsenide on Si (InGaAs/Si), Aluminum Indium Nitride on Si (AlInN/Si), Gallium Indium Nitride on Si (GalnN/Si), and other types of suitable semiconductor heterostructures. To avoid crystalline mismatches between the semiconductor component 102 and the substrate layer 104, their lattice constants are preferably matched to one another. For instance, in embodiments where the semiconductor component 102 is a III-V semiconductor component 106, the substrate layer 104 can have a layer of a lattice matched crystalline material such as monocrystalline germanium, as germanium has a lattice constant substantially close to that of III-V semiconductors such as GaAs, InGaAs, GaInP, AlGaAsP, InGaAsP, AlGaInP, InAIGaP, InGaAIP, AlInGaP and the like.

As shown in this embodiment, the substrate layer 104 has a first surface 104a which is made integral to the semiconductor component 102, and a second surface 104b opposite to the first surface 104a. As depicted, the second surface 104b has a given surface roughness 108 in this example. The illustrated surface roughness 108 can result from a manufacturing step in which the optoelectronic device 100 is detached from a wafer of monocrystalline germanium.

More specifically, in this example, the surface roughness 108 includes a plurality of protrusions protruding from the second surface 104b of the substrate layer 104. The protrusions can take the form of an irregular, e.g. random, distributions of broken pillars 110 such as shown in FIG. 1A. It is noted that in some embodiments, the broken pillars 110 can have a depth, normal to the surface 104, of between 10 and 50 nm for instance, and a diameter ranging from about 20 nm to about 500 nm, more frequently between about 50 nm to about 200 nm. Annealing the substrate subsequently to its detachment from the wafer of monocrystalline germanium may lead to broadening of the diameter and shortening of the protrusions, such as represented by FIG. 1A where the substrate was not annealed subsequent to detachment, FIG. 1B where the substrate was annealed at 650° C. for one hour subsequent to detachment, FIG. 1C where the substrate was annealed at 700° C. for one hour subsequent to detachment, and FIG. 1D where the substrate was annealed at 750° C. for one hour subsequent to detachment, with a microscope image of protrusions being presented at the upper portion of each figure and a graph plotting the diameter distribution presented at the bottom of each figure. In some embodiments, the broken pillars may be left untouched after the detachment of the optoelectronic device from the remaining wafer portion. In some other embodiments, the broken pillars 110 can be processed or otherwise removed for surface roughness reduction, as will be discussed further below.

In accordance with one example, a removable germanium (Ge) layered component is formed including performing, at a first, low temperature (e.g. below 400° C.; between 80 and 400° C., between 150 and 350° C., or between 200 and 300° C.), deposition of a first non-porous layer of monocrystalline Ge onto an exposed surface of a substrate of porous monocrystalline Ge. The deposition leads to monocrystalline structure in the first non-porous layer via epitaxy with the porous monocrystalline Ge substrate. The deposition of the first non-porous layer being performed using a first precursor which can work at lower temperatures, such as digermane (Ge2H6), or in some embodiments germane GeH4, GeHCl3, GeH2Cl2 or GeH2. Such precursors may be relatively expensive but the inconvenience of the expensiveness can be alleviated by making the first non-porous layer relatively thin, such as between 10 and 100 nm. In this example, depositing this first layer at low temperatures allows to preserve the monocrystalline structure of the porous Ge substrate and thereby leads to a monocrystalline structure in the first non-porous layer via epitaxy with it. This first non-porous layer now forms a template for subsequent crystalline growth, e.g. epitaxy.

At this point, the temperature is increased to a “high” temperature, such as above 400° C., preferably around 500° C. There can be different advantages to increasing the temperature for deposition of a second non-porous layer of monocrystalline Ge onto the first layer. Firstly, at high temperature, precursors which do not work well at lower temperatures may be used, and such precursors, such as GeCl4 for instance, can be significantly lower in cost that precursors which can operate at lower temperatures, opening the doors of many industrial applications. Secondly, crystal quality, such as can be measured by electronic properties of the crystal for instance, is generally better when a crystal is epitaxially grown at higher temperatures. At this high temperature, the second layer deposited has a thickness substantially greater, e.g. an order of magnitude greater or more, than the first layer, such as between a micron and one or more tens of microns for instance, depending on the application, and overall represent a lower cost.

At this point, additional layers, of Ge or other materials (e.g. one or more layers of III-V semiconductor crystalline materials in opto-electrical device applications), can be deposited, or not, onto the second layer.

Once all desired layers have been deposited, the porous layer underneath the first layer, which at this point can represent a structurally weak layer, can be used as a means to allow separation of the first, second, and any additional layers from the substrate. More specifically, the first, second, and any additional layers can be pulled off the substrate (e.g. “peeled”).

In one embodiment, the substrate can have a bulk layer of non-porous monocrystalline Ge, and a porous layer can be formed on the exposed face (e.g. by etching or any suitable technique to form a porosity between 10 and 90%, preferably between 30 and 70%, or between 30 and 60% or between 35 and 55%, or between 40 and 50% depending on the applications. The porous layer of monocrystalline Ge can be relatively thin, such as a few microns to a few hundred microns, e.g. between 100 and 400 nm for instance, allowing the bulk layer of the non-porous monocrystalline Ge underneath the porous layer to be re-used to form another porous layer on the exposed face, and further depositions, once the previously deposited layers have been pulled off.

In some embodiments, it can be preferred to perform an annealing step at high temperature (e.g. between 400 and 600° C.) between the deposition of the first and the second layer. The annealing step was used in some embodiments and lead to satisfactory crystal quality. Such a high temperature annealing step may have an effect on the re-structuring and stabilization of the porous layer.

In some embodiments, a chemical cleaning step can be performed on the porous monocrystalline Ge layer prior to the deposition of the first non-porous layer. The chemical cleaning step can involve removing surface oxidation from the exposed surface, and replacing the surface oxidation by halogen surface terminations. This can involve using a halogen in a solution for instance. In some embodiments, it was found that using a solvent in the solution as well, or as a preceding step on the exposed surface of the porous monocrystalline layer, could favor the penetration of the halogen into the pores, which can be desired. The solvent can be ethanol or isopropyl (IPA) for instance. The halogen can be brome for instance. Hydrogen bromide in particular was found to generate satisfactory results in some embodiments. Indeed, if the exposed face of the porous layer is formed, handled and/or stored in an oxygenated environment prior to deposition of the first layer, the exposed layer can become oxidised which may impede the epitaxial growth of subsequent layers unless addressed. Chemical cleaning can address the oxidation by replacing the surface oxidation by halogen surface termination. Alternate halogens which may be suitable in some embodiments include hydrogen fluoride, hydrochloride, hydrogen iodide.

In some embodiments, it can be desirable to remove at least some, if not all, the halogen surface terminations prior to deposition of the first non-porous layer onto the exposed surface. Indeed, the presence of the halogen surface termination may impede the epitaxial growth, or otherwise said the “copying” of the crystalline structure. A step of annealing at low temperature, for a certain period of time (e.g. minutes) may be useful to this end. The step of annealing can be performed in a non-oxygenated environment, such as in a specialized oven. In some embodiments, the assembly can remain in the oven for subsequent layer depositions, and even for peeling. A balance may need to be reached in the choice of the temperature in view of a specific embodiment. Indeed, on one hand, higher temperatures may be more efficient at removing the halogen terminations, but on the other hand, the halogen terminations may not need to be entirely removed and higher temperatures may cause transformation of the porous structure. Depending on the embodiment, suitably low annealing temperatures for such an initial, low-temperature, annealing step can be between 100 and 400° C., preferably between 200 and 300° C., for instance. The time period for the annealing may vary from one embodiment to another, and in some cases a few minutes may be sufficient. Annealing can typically be performed for a longer period of time than required, but the additional period of time may represent a loss of productivity, and therefore, annealing times between a few minutes and an hour can be preferred in some embodiments.

Following detachment, the remaining wafer portion can be used for the subsequent manufacture of a number of other optoelectronic devices, thereby reducing the amount of costly, monocrystalline germanium used as substrate per optoelectronic device.

Prior to the formation of a new porous layer on the exposed face of the Ge substrate, a step of polishing can be performed. The polishing can be performed by CMP, chemical etching, electrochemical polishing, or any other suitable technique.

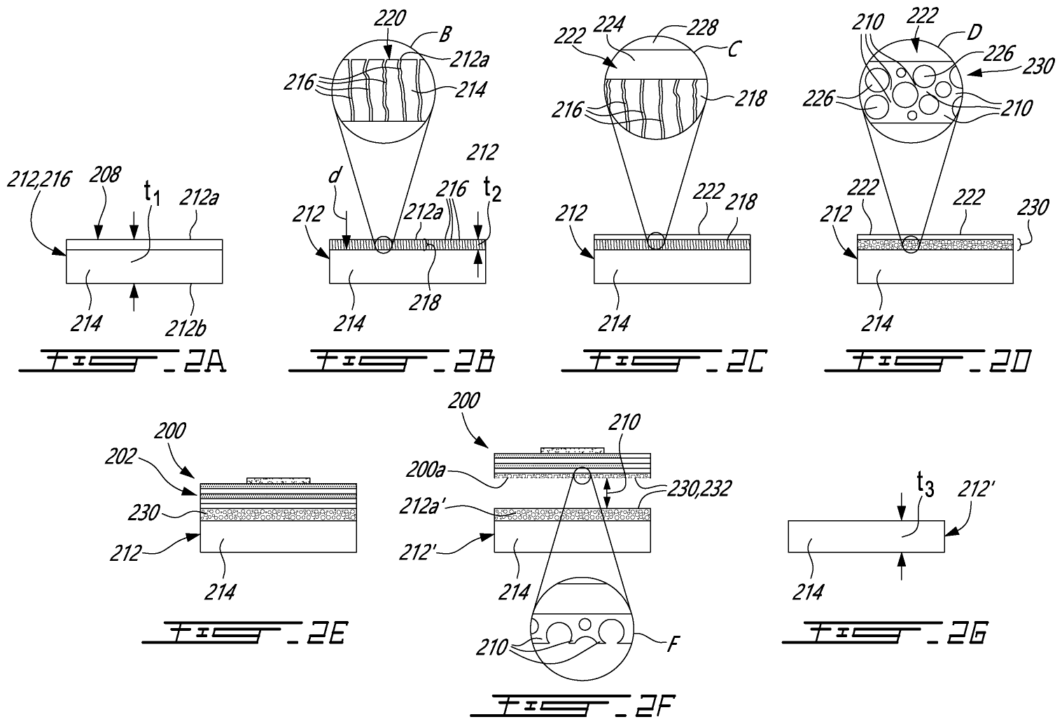

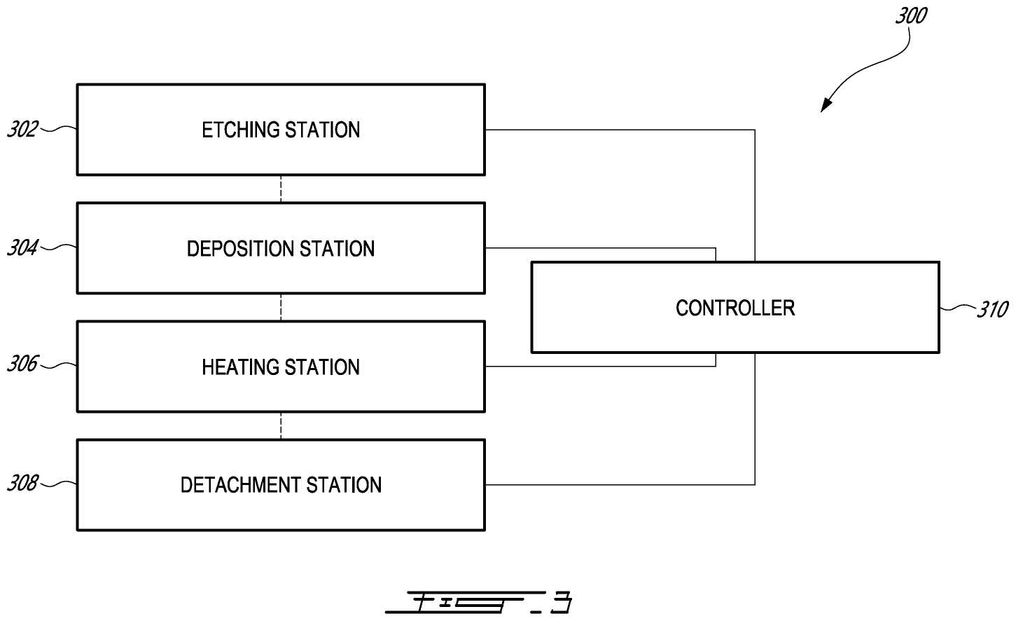

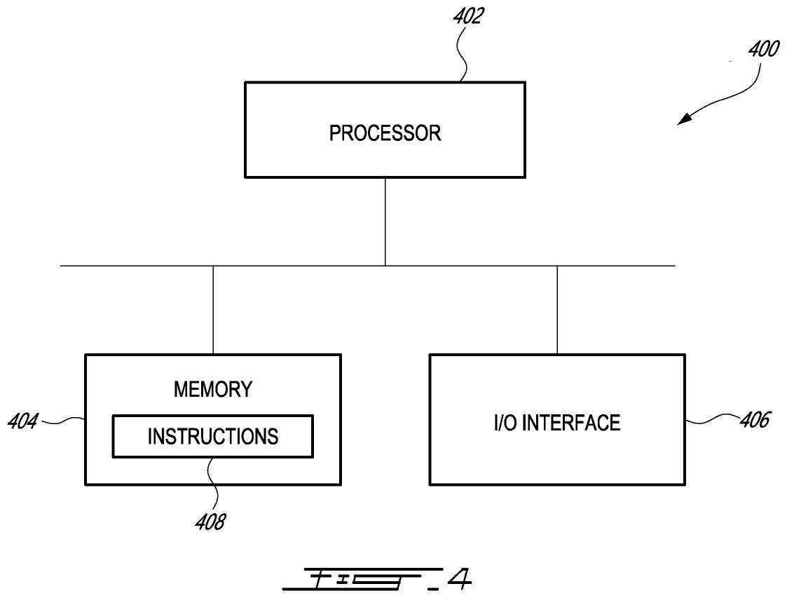

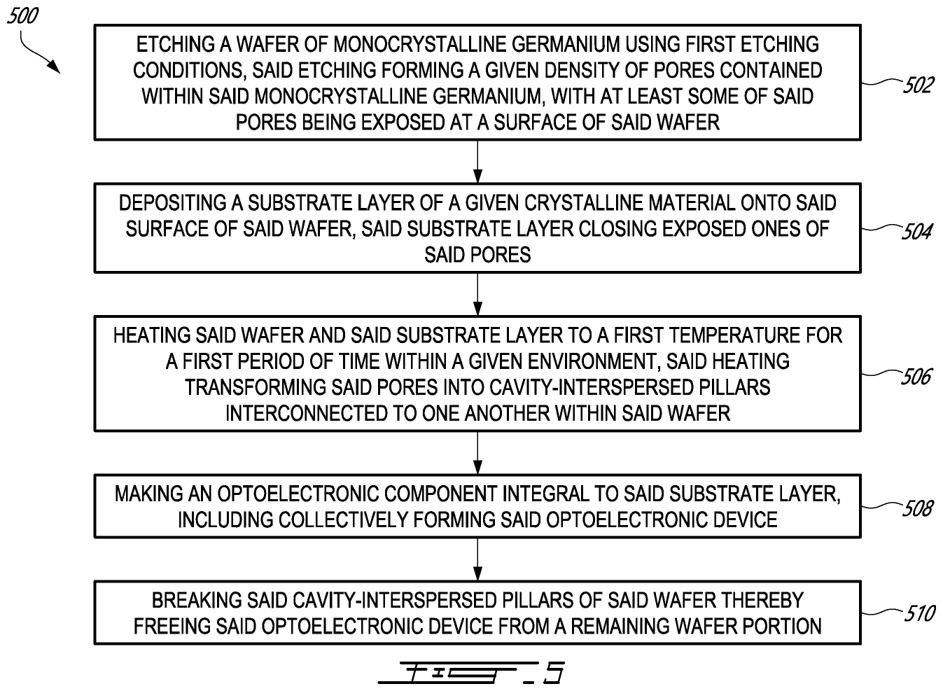

More specifically, in accordance with one example, for the optoelectronic device 100 to be detachable from a wafer of monocrystalline germanium, a number of steps can be performed as described below with reference to FIGS. 2A through 2G.

FIG. 2A shows an example of a wafer 212 of monocrystalline germanium 214. As shown, the wafer 212 has a sheet-like body 216 having a first wafer surface 212a and a second wafer surface 212b opposite to the first wafer surface 212a. The wafer 212 of monocrystalline germanium 214 is used as a basis for the manufacture of one or more optoelectronic devices such as the one described with reference to FIG. 1. Referring back to FIG. 2A, a first thickness t1 of the wafer can vary from one embodiment to another. For instance, the first thickness t1 of the wafer 212 can range between about 50 urn and about 1 cm or more, preferably range between about 0.01 mm and about 0.2 mm, and most preferably between about 0.15 mm and about 0.6 mm. In some embodiments, a given one of the first and second wafer surfaces 212a and 212b has a surface roughness 208 which exceeds a predetermined surface roughness threshold. In these embodiments, the surface roughness of the given wafer surface(s) 212a and 212b may be reduced by cleaning or other suitable surface processing step(s).

FIG. 2B shows the wafer 212 of FIG. 2A after an etching step. The etching step includes the etching of the wafer 212 of monocrystalline germanium 214 with first etching conditions. The etching step forms a given density of pores 216 contained within the monocrystalline germanium 214. As shown in this embodiment, the pores 216 extend from the first wafer surface 212a up to a given depth d within the thickness t1 of the wafer 212, thereby forming a pore containing layer 218 in the wafer 212 of monocrystalline germanium 214. The pores 216 can extend in a substantially perpendicularly or obliquely with respect to the first wafer surface 212a. In some embodiments, the pore containing layer 218 can have a second thickness t2 ranging between about 10 nm and 100 um, preferably between about 50 nm and 10 μm, and most preferably between about 200 nm and 2 μm. Accordingly, some of the pores 216 are exposed at the first wafer surface 212a of the wafer 212, such as shown in inset B. The first etching conditions are such that the pores 216 are formed at a density ranging between about 35% and 65%, and preferably at about 50%. For instance, in some embodiments, a density of 10% was achieved with some etching and heating conditions. In this disclosure, the density is defined by the ratio between the amount of void within the pore containing layer and the total volume of the pore containing layer.

As depicted, the exposed pores 216 generally create an undesired surface roughness 220 which is ill-suited for the growth of semiconductor components thereon. To reduce the surface roughness 220, and suitably prepare the first wafer surface 212a for the reception of a semiconductor surface, a substrate layer 222 of a given crystalline material 224 is deposited on the first water surface 212a of the wafer 212, such as shown in FIG. 2C. By doing so, the exposed ones of the pores 216 are closed by the substrate layer 222, leaving an exposed surface 228 of reduced surface roughness atop the wafer 212, such as shown in inset C.

FIG. 2D shows the wafer 212 of FIG. 2C after a heating step in which the wafer 212 and the substrate layer 222 are heated to a first temperature for a first period of time within a given environment. As can be expected, such heating can transform the pores 216 into cavity-interspersed pillars 210 interconnected to one another such as shown in inset D. It is understood that the cavity-interspersed pillars 210 collectively reduce the integrity of the wafer 212 where the interconnected pillars 210 and cavities 226 are distributed. Accordingly, the heating step transforms the pore containing layer 218 into a reduced integrity layer 230 by the heating step. In some embodiments, the heating step also contributes in reducing the surface roughness 228 atop the substrate layer 222.

In a following step, illustrated in FIG. 2E, a semiconductor component 202 is made integral to the exposed surface of the substrate layer 222. The semiconductor component 202 can be any suitable type of semiconductor component such as those enumerated above. The semiconductor component 202 can be deposited on the substrate layer 222 in one or more steps. For instance, the semiconductor component 202 can be made by depositing a series of layers atop each other using conventional epitaxial growth techniques, chemical vapor deposition techniques and the like. Once deposited, the semiconductor component 202 and the substrate layer 222 collectively form an optoelectronic device 200 which lies on the reduced integrity layer 230 of the wafer 212 of monocrystalline germanium 214.

The optoelectronic device 200 is detached from the wafer 212 of monocrystalline germanium 214, leaving a remaining wafer portion 212′, as shown in FIG. 2F. For instance, the optoelectronic device 200 can be detached from the wafer 212 by breaking the reduced integrity layer 230. In some embodiments, the optoelectronic device 100 may be pulled away from the wafer 212, or vice versa. The optoelectronic device 100 can be detached using a mechanical force applied using an adhesive, such as epoxy or tape, an ultrasound beam, a water jet and the like. The resulting substrate layer of the optoelectronic device 100 can range from 10 nm to 400 nm, for instance. In some other embodiments, the optoelectronic device 200 can be deposited on another substrate using flip-chip deposition techniques and the like. As shown, the detachment can leave an undesirable surface roughness 232 resulting from the breaking of the reduced integrity layer 230. Accordingly, by breaking the interconnected pillars 210, the under surface 200a of the optoelectronic device 200 and the upper surface 212a′ of the remaining wafer portion 212′ show broken interconnected pillars 210 protruding from their respective surfaces 200a and 212a′.

As the surface roughness 232 of the under surface 200a of the optoelectronic device 200 may be kept as is without inhibiting the working of the optoelectronic device 200, the surface roughness 323 of the upper surface 212a′ of the remaining wafer portion 212′ may be cleaned or otherwise removed in some embodiments. Indeed, the broken interconnected pillars 210 may be removed from the remaining wafer portion 212′ in one or more surface processing steps, the result of which being shown in FIG. 2G. The processing of the surface can include wet chemical etching step(s), chemical treatment step(s) and chemical-mechanical polishing (CMP) step(s), depending on the embodiment. As can be appreciated, the remaining wafer portion 212′ of FIG. 2G is similar to the original wafer 212 of FIG. 2A, only with a reduced thickness. For instance, the remaining wafer portion 212′ can have a third thickness t3 being smaller than the first thickness t1, i.e., t3<t1. Accordingly, the remaining wafer portion 212′ may be used as a basis for the manufacture of one or more other optoelectronic devices (not shown). In other words, the steps described with reference to FIGS. 2A-2G can be repeated a number of times. In such a case, the processing steps shown in FIGS. 2A-2G would be repeated one or more times. Prior to its re-use, the remaining wafer portion 212′ can be surface reconditioned.

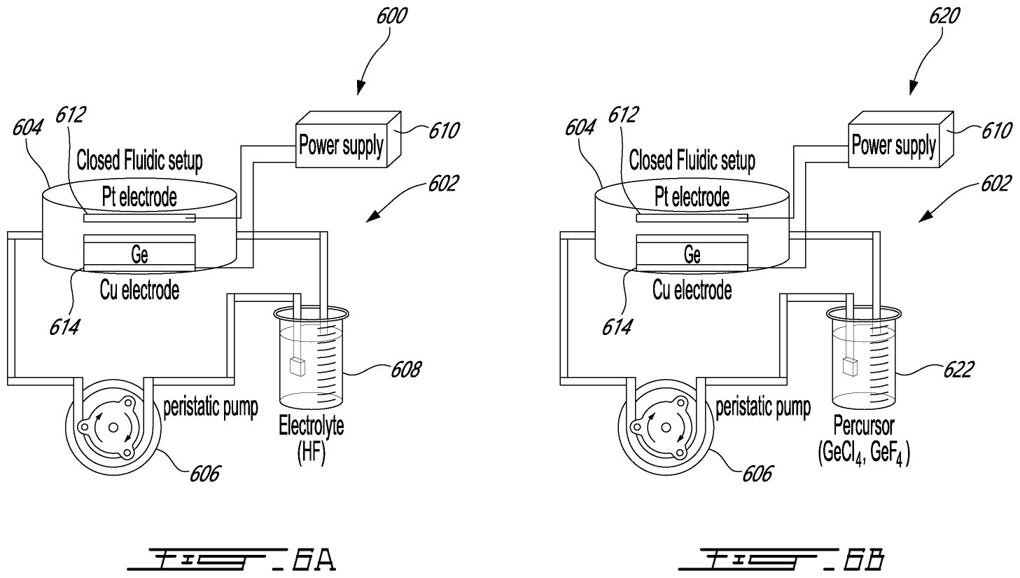

These processing steps, as well as other processing steps described below, can be performed by a substrate manufacturing system 300, an example of which is shown in FIG. 3. As depicted, the substrate manufacturing system 300 has an etching station 302, a deposition station 304, a heating station 306 and a detachment station 308 in this embodiment. Other potential stations may be part of the substrate manufacturing system 300 in some embodiments.

For instance, the etching station 302 can perform the etching step discussed above with reference to FIG. 2B. More specifically, the etching station 302 can create the first etching conditions, or any other etching conditions, with which the desired density of pores can be formed within the pore containing layer of the wafer of monocrystalline germanium. In some embodiments, the etching station 302 may incorporate one or more electrochemical systems with one or more galvanostatic cells, one or more power supplies and the like.

In some embodiments, the deposition station 304 can be used to deposit the substrate layer on the wafer of monocrystalline germanium, such as discussed above with reference to FIG. 2C. In some embodiments, the deposition station 304 can incorporate a chemical vapour deposition system, an epitaxy reactor, and any other similar deposition system. In some embodiments, the deposition station 304 can include a surface preparation station to prepare the surfaces on which deposition or growth is to be performed. However, the surface preparation station can be remote from the deposition station 304 in some other embodiments.

The heating station 306 can perform the heating step discussed above with reference to FIG. 2D. As such, the heating station 306 can heat the wafer and the substrate layer up to a given temperature for a given period of time within a controlled environment comprising a given gas, for instance. The given gas can contain at least 10% of hydrogen mixed with nitrogen, pure hydrogen or in a vacuum. The given gas can vary from one embodiment to another. However, an environment exempt of oxygen was found preferable in at least some embodiments. It is noted that the heating station 306 may incorporate a rapid thermal annealing system and the like. In some embodiments, the deposition station 304 and the heating station 306 are part of a single station.

In some embodiments, a station is used to make a semiconductor component integral to the substrate layer such as discussed with reference to FIG. 2E. In some embodiments, such a station may be provided in the form of deposition station which can deposit a series of semiconductor layers atop each other using conventional epitaxial growth techniques to form the semiconductor component. In some embodiments, the deposition station 304 may be used both to deposit the substrate layer atop the wafer and to deposit the semiconductor component atop the substrate layer. In some embodiments, the semiconductor component can be received as is from a semiconductor component manufacturer and deposited or otherwise made integral to the substrate layer. In such embodiments, the deposition station 304, or any other suitable station, can be configured to pick up the semiconductor component and to deposit or otherwise mount it to the substrate layer.

As shown, the detachment station 308 is configured to detach the optoelectronic device from the remaining wafer portion, such as described above with reference to FIG. 2F. The detachment station 308 may have one or more movable parts, such as robotized arms, which are configured to pull the optoelectronic device away from the remaining wafer portion, thereby breaking the reduced integrity layer of the wafer of monocrystalline germanium. In some embodiments, the pulling force may be exerted on the optoelectronic device while maintaining the remaining wafer portion fixed, or vice versa.

It will be understood that all stations can be integrated to an oven in some embodiments, and that in other embodiments some of the stations can be separate from the oven, meaning that the sample may need to be moved from the oven to another location in such other embodiments.

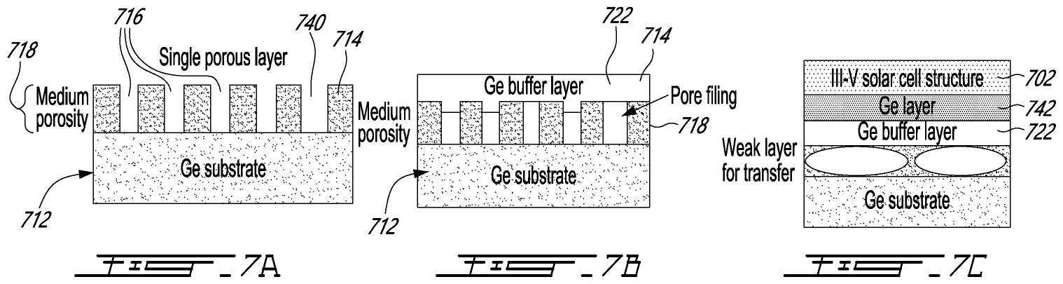

As shown in the depicted embodiment, the stations 302, 304, 306 and 308 can be communicatively coupled to a controller 310 controlling each of the stations and components thereof sequentially performing processing steps on the wafer of monocrystalline germanium discussed above. The controller 310 can be provided as a combination of hardware and software components. In some embodiments, the controller 310 encompass any controller portions which may be part of some of the individual stations. As such, regardless of the controller portions being separate from one another, and because the controller portions are communicatively coupled to one another, they form the controller 310. The hardware components can be implemented in the form of a computing device 400, an example of which is described with reference to FIG. 4.

Referring to FIG. 4, the computing device 400 can have a processor 402, a memory 404, and I/O interface 406. Instructions 408 for performing at least some of the processing steps discussed herein can be stored on the memory 404 and accessible by the processor 402.

The processor 402 can be, for example, a general-purpose microprocessor or microcontroller, a digital signal processing (DSP) processor, an integrated circuit, a field-programmable gate array (FPGA), a reconfigurable processor, a programmable read-only memory (PROM), or any combination thereof.

The memory 404 can include a suitable combination of any type of computer-readable memory that is located either internally or externally such as, for example, random-access memory (RAM), read-only memory (ROM), compact disc read-only memory (CDROM), electro-optical memory, magneto-optical memory, erasable programmable read-only memory (EPROM), and electrically erasable programmable read-only memory (EEPROM), Ferroelectric RAM (FRAM) or the like.

Each I/O interface 406 enables the computing device 400 to interconnect with one or more input devices, such as keyboard(s), mouse(s) and the like, or with one or more output devices such as display(s), memory system(s), network(s) and the like. The I/O interface 406 can also enable the computing device 400 to interconnect with the stations 302, 304, 306 and 308, or to components thereof including, but not limited to, crystalline material source(s), etchant source(s), robotized arm(s) and the like.

Each I/O interface 406 enables the controller 310 to communicate with other components, to exchange data with other components, to access and connect to network resources, to server applications, and perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fiber optics, satellite, mobile, wireless (e.g. Wi-Fi, WiMAX), SS7 signaling network, fixed line, local area network, wide area network, and others, including any combination of these.

The computing device 400 and any software application operated by the computing device 400 described herein are meant to be examples only. Other suitable embodiments of the controller 310 can also be provided, as it will be apparent to the skilled reader.

FIG. 5 shows a flow chart of an example of a method 500 of manufacturing one or more optoelectronic device(s). At least some of the steps of the method 500, or any other method(s) described herein, can be partially or wholly performed by the substrate manufacturing system 300 described with reference to FIG. 3.

At step 502, a wafer of monocrystalline germanium is etched using first etching conditions. The step 502 of etching forms a given density of pores contained within the monocrystalline germanium, with at least some of the pores being exposed at a surface of said wafer. In some embodiments, the density of the pores ranges between about 35% and said 65%. Most preferably, the density of the pores is about 50%.

At step 504, a substrate layer of a given crystalline material is deposited onto the surface of the wafer of monocrystalline germanium. The deposition of the substrate layer closes exposed ones of the pores formed at step 502. The closing of the pores can reduce a surface roughness of the so-processed wafer of monocrystalline germanium.

In some embodiments, the substrate layer is an epitaxial growth ready layer which can receive one or more semiconductor layers via conventional epitaxial growth techniques, for instance.

In some embodiments, the given crystalline material of which the substrate layer is made is monocrystalline germanium. In such embodiments, both the wafer and the substrate layer are made of monocrystalline germanium, which may reduce the amount of crystalline mismatch occurring between the substrate layer and the wafer and/or between other deposited semiconductor layers that have close lattice constants.

In some other embodiments, the given crystalline material of the substrate layer is different from the crystalline material of the wafer. For instance, in some embodiments, the substrate layer is made of precursors such as GeCl₄ and/or GeF₄ that are electroplated to the exposed surface of the wafer.

At step 506, the wafer and the substrate layer are heated up to a first temperature for a first period of time within a given environment. The step 506 of heating transforms the pores into cavity-interspersed pillars interconnected to one another within the wafer. In other words, the step 506 of heating expands the pores into cavities which are distributed within the monocrystalline germanium and defined by a surrounding gallery of interconnected pillars. As discussed, the cavities can collectively reduce the integrity of the monocrystalline germanium within a reduced integrity layer. The interconnected pillars thereby preventing the reduced integrity layer from collapsing.

In some embodiments, the steps 502 of etching and 506 of heating are such as that it results in cavity-interspersed pillars having a dimension ranging from about 20 nm to about 500 nm.

At step 508, a semiconductor component is made integral to the substrate layer. The resulting semiconductor component collectively form an optoelectronic device along with the substrate layer. The semiconductor device can be made by depositing one or more layers of semiconductor layers onto the surface of the wafer. In some embodiments, the semiconductor layers can include III-V semiconductor crystalline materials.

Accordingly, at step 510, the cavity-interspersed pillars of the reduced integrity layer are broken, thereby freeing the optoelectronic device, comprising both the semiconductor component and a portion of the substrate layer to which the semiconductor component is made integral, from a remaining wafer portion.

In some embodiments, the resulting, broken cavity-interspersed pillars are removed or otherwise cleaned from the surface(s) of the optoelectronic device and/or of the remaining wafer portion.

In some embodiments, the remaining wafer portion is used as a wafer of monocrystalline germanium for the manufacture of another optoelectronic device. In these embodiments, the steps of the method 500 are repeated using the remaining wafer portion is as the wafer of monocrystalline germanium. In this way, the same wafer of monocrystalline germanium may be used once, twice or more to produce one, two or more optoelectronic devices. The remaining wafer portion can be surface reconditioned prior to its re-use. For instance, the remaining wafer portion may be exposed to wet chemical etching steps, mechanical cleaning steps and/or chemical-mechanical polishing steps.

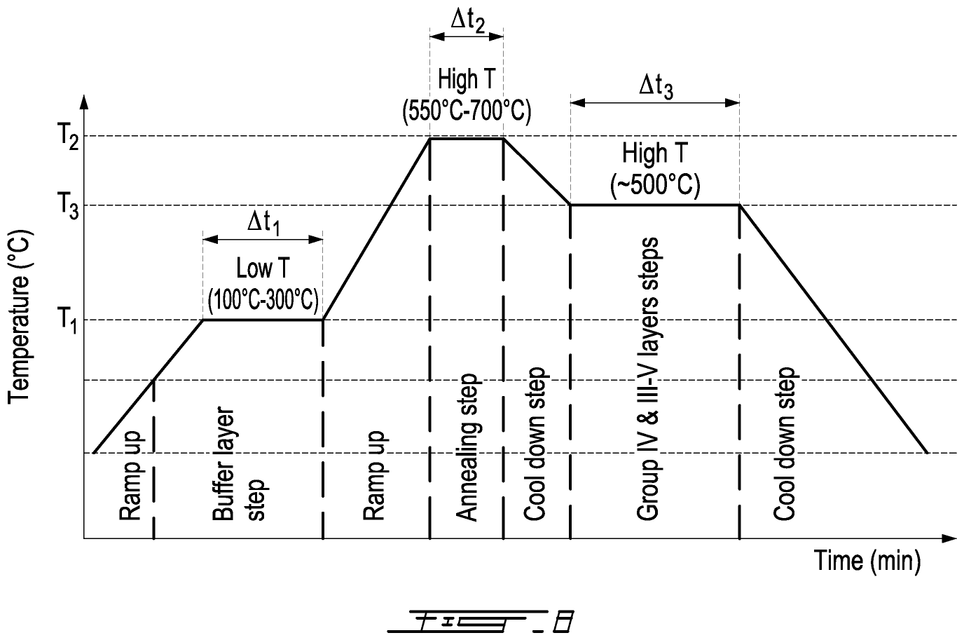

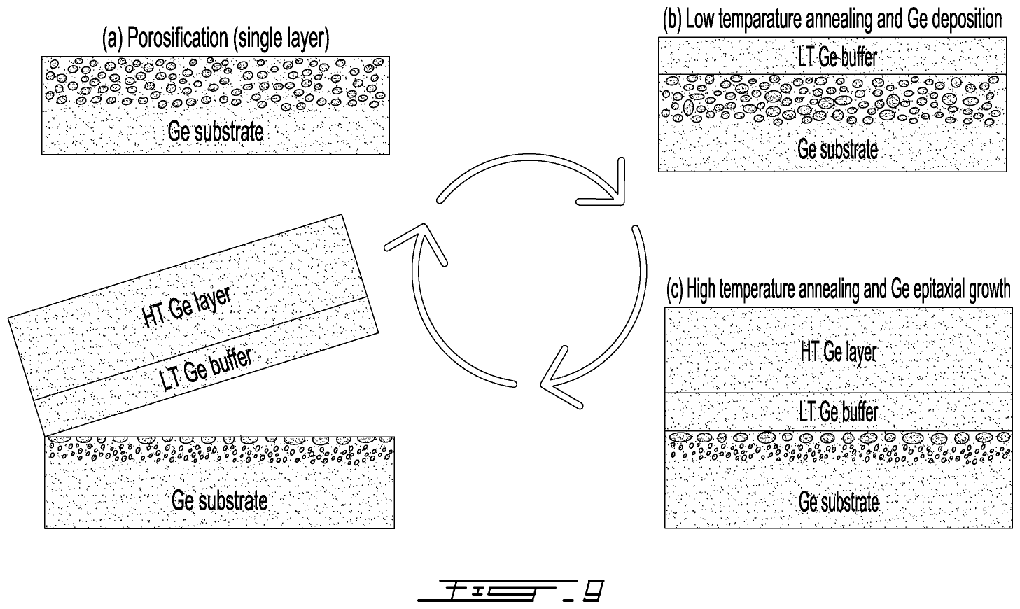

Reference is now made to FIG. 6A which shows an example of an etching station 600, in accordance with an embodiment. As depicted, the etching station 600 has a closed fluidic setup 602 having a container 604, a pump 606, an electrolyte source 608 which are in fluid communication with one another. As the pump 606 can be useful in some embodiments, it is only optional as it may be omitted in some other embodiments. A power supply 610 is provided to apply an electrical signal to electrodes 612 and 614 immersed in the container 604 and between which a wafer to be etched is disposed. The type and concentration of electrolyte provided by the electrolyte source 608, along with the parameters of the electrical signal, such as amplitude, frequency and the like, define the etching conditions with which the wafer is etched in the etching station 600. In this specific example, the etching conditions provided form the given density of pores in the wafer of monocrystalline germanium. The thickness of the so-formed pore containing layer generally ranges between about 50 nm and about 10 μm, and most preferably between about 200 nm and about 2 μm. FIG. 6B shows an example of a deposition station 620 and more specifically of an electrodeposition station. As shown in this specific example, the deposition station has a closed fluidic setup 602 having a container 604, a pump 606, a Ge-based source 622 which are in fluid communication with one another. Again, the pump 606 may be optional in some embodiments. A power supply 610 is provided to apply an electrical signal to the electrodes 612 and 614 immersed in the container 604 and between which the wafer to be processed is disposed. In this specific example, the deposition station 620 of FIG. 6B is similar to the etching station 600 of FIG. 6A, except that the electrolyte source 608 has been removed and replaced with the Ge-based source 622, which can be provided in the form of a precursor source. In some other embodiments, the etching and deposition stations 600 and 620 can be independent from one another. In this specific embodiment, the deposition station 620 can be used to deposit a substrate layer made of precursors provided by the Ge-based source 622. The substrate layer may have a thickness ranging between about 50 nm and about 2 um, and preferably between 100 nm and 500 nm.

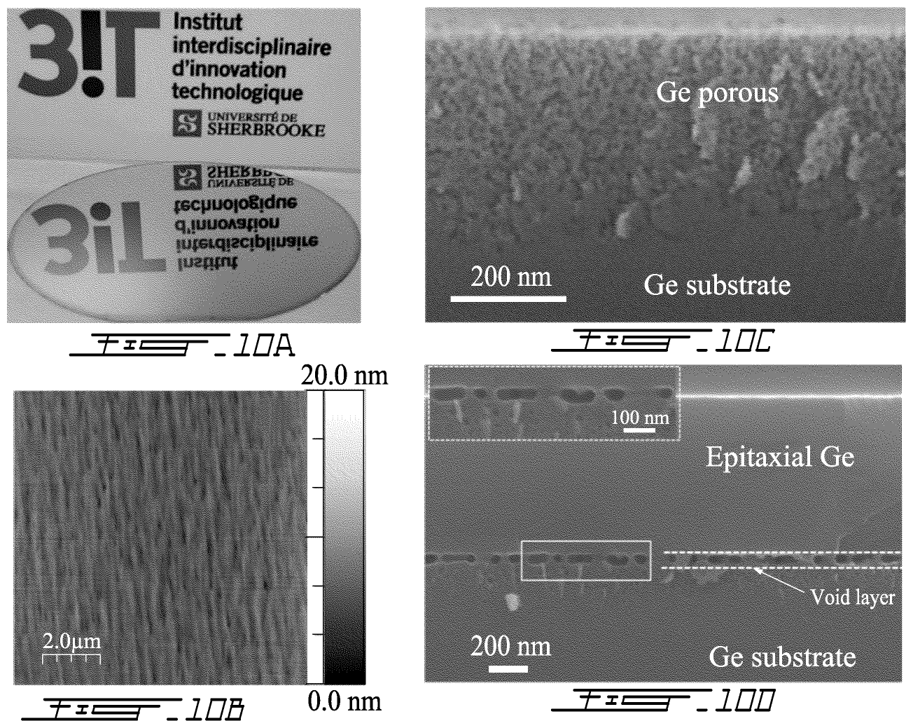

FIG. 7A shows an example wafer 712 of monocrystalline germanium 714 after an etching step forming a given density of pores 716 within the wafer 712. As shown, the density of pores 716 is about 50% in this example, meaning that 50% of the pore containing layer 718 is associated with pore void 740 whereas the other 50% is monocrystalline germanium 714. In some embodiments, the substrate layer may not be made of precursors. Instead, the substrate layer is made of monocrystalline germanium. In such embodiments, such as the one shown in FIG. 7B, a substrate layer 722 of monocrystalline germanium 714 may be deposited on the exposed pores 716 of the pore containing layer 718 of the wafer 712. After a heating step such as the one described above, a semiconductor component 702 may be made integral to the substrate layer 722 for later detachment from the remaining wafer portion. As shown in this embodiment, an optional germanium layer 742 may be deposited atop the substrate layer 722, after the heating step but prior to the deposition of the semiconductor component 702. Such an optional germanium layer 742 may help reducing the surface roughness atop the substrate layer 722 to suitably receive the optoelectronic component 702, for instance. FIG. 7C shows an example optoelectronic component 702, provided in the form of a III-V solar cell structure in this specific example, received atop the optional germanium layer 742. Any other optoelectronic component could have been deposited on the germanium layer 742, depending on the embodiment.

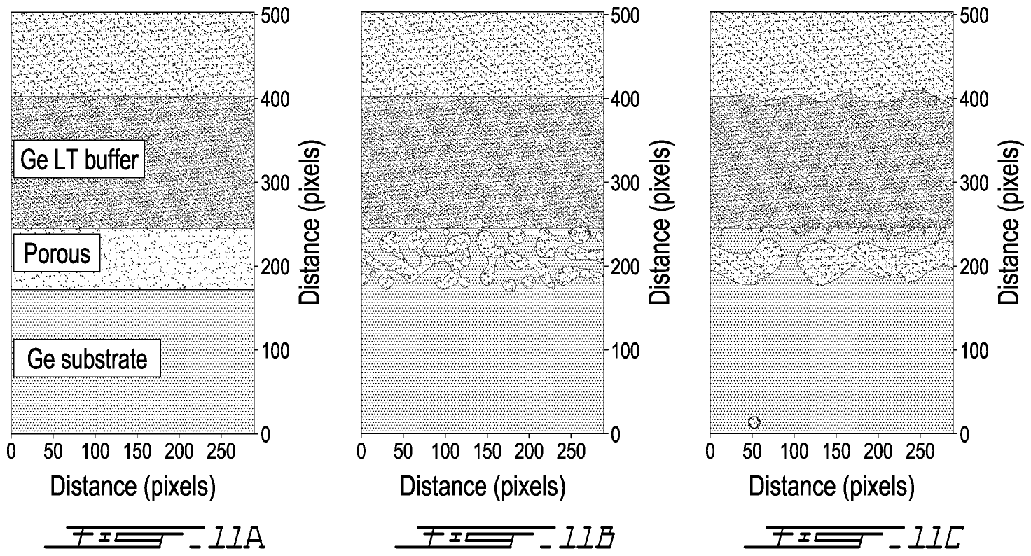

FIG. 8 shows a graph of the temperature at which the wafer 712 and other components are heated during an example method of manufacturing an optoelectronic device. In this specific embodiment, the temperature is increased up to a first temperature T1 of about 100°-300° C. and maintained at that temperature for a first period of time Δt1. The first period of time Δt1 may be defined so as to avoid reorganization of the porous layer. The temperature is then increased up to a second temperature T2 of about 450°-700° C. and maintained at that temperature for a second period of time Δt2. The second period of time Δt2 may be defined so as to ensure the reorganization of the porous GE to obtain the cavities and interpillars. The temperature is then decreased to a third temperature T3 of about 500° C. or more and maintained at that temperature for a third period of time after which the temperature is decreased until room temperature is reached. Although 500° C. was achieved with the heating station used in this experiment, other heating stations which can achieve higher temperatures, such as 600° C. or more, could be used as well in some other embodiments. In this specific embodiment, the substrate layer deposition step can be performed during the first period of time Δt1, the heating step can be performed during the second period of time Δt2, and the semiconductor component making step can be performed during the third period of time Δt3.

### Example—Homoepitaxial Growth of 4-Inch Ge Single Crystal on Electrochemical Etched Porous Ge Surface

Germanium (Ge) has attracted considerable attention as potential semiconductor materials with a long history of extensive research behind it, including the first transistor demonstration. The attractiveness of Ge is fostered by its superior properties, including its higher electron and hole mobilities, and a strong absorption coefficient (˜2500 cm⁻¹) in 1.3-1.55 μm wavelength range. Furthermore, its appropriate band gap of 0.66 eV allows for efficient infra-red detection in opto-electronic devices. Indeed, it lends itself well to use in countless electronic applications, especially in areas of photovoltaic solar cells. In fact, Ge is known to be an excellent bottom junction material in a multi-junction solar cell (MJSC) based on GaInP/GaAs/Ge. Being compatible with III-V semiconductors (i.e: almost matched lattice constant and thermal expansion coefficient), the Ge junction is considered as an important part of this solar cell architecture, contributing about 10% to the photovoltaic performances of the MJSC. However, while improving the efficiency of solar cells, the cost should also be considered. It is noteworthy that a thicker Ge wafer substrate contributes significantly to the III-V solar cell costs. In addition, it can potentially hinder the photovoltaic performances of the entire device, by affecting the photogenerated electron-hole pair, their collection and thereby increasing the recombination rate. Conversely, reducing the Ge substrate thickness would definitely enable an efficient carrier collection, and would be beneficial for the overall cost-reduction of the device.

Consequently, there has been a sustained R&D effort to develop many different strategies for potential substrate cost-reduction. Most of the work reported so far pointed out the appealing approaches based on substrate removal and reuse strategies. Epitaxial lift-off (ELO) via sacrificial etch layer is one of these technologies, that permits to separate the active layers from their parent substrates, and offers the possibility of multiple wafer re-uses. However, it is widely applied for detachment of III-V semiconductors layers. In principle, a lattice-matched release layers like AllnP or AlAs can be inserted between the substrate and the active layers based on III-V semiconductors (i.e. GaAs). At the end of the growth, the epi-structure is subjected to a chemical etching involving the use of a highly corrosive chemical etchants, like hydrofluoric acid (HF) or hydrochloric acid (HCl) to selectively remove the sacrificial layer without damaging the active layers (membrane). However, despites the perfect etch selectivity of the sacrificial material over the rest of the epi-stacks, the etching duration may vary from a few hours to a few days in a case of wafer scale, which may impose practical limitations for large-volume production. Moreover, the increased surface roughness of the parent substrates and the remaining residues generated by wet-chemical etching during ELO, call for complex and multi-steps processing (i.e chemical mechanical polishing), typically required to restore the parent substrate surface to an epi-ready condition suitable for regrowth of additional device. Another wafer reuse possibilities were also demonstrated such as, Laser lift-off and controlled spalling. Although the development of these approaches have been ongoing for years, none of the aforementioned technologies thoroughly addresses the Ge substrate re-use.

In order to improve the wafer re-use process throughput, another cost reduction possibility is demonstrated by a porous release-layer approach. This process can make use of the formation of an embedded lower-density layer which can alternately be referred to as a voids layer at the epitaxial Ge/PGe interface, which is associated to the reorganization of the porous layer under a high temperature annealing. Therefore, by applying an external stress, the Ge nanomembrane (Ge NM) can be successfully removed from its parent substrate.

Such a technique can be used to develop a weak porous release layer for Ge substrate re-use. For instance, the effect of varying porosities and annealing step on the cavity formation and the surface quality of reorganized PGe can be analyzed and can reveal a significant increase in PGe surface roughness (from 0.31 to 7.85 nm) after an annealing in hydrogen atmosphere. However, such a high roughness may adversely affect the homoepitaxial growth of Ge. Processing parameters, such as annealing time, temperature and PGe layer thickness, can have effects on the morphological transformation and the crystallinity of PGe. There can be significant evolution of the PGe morphology during a long annealing time. In addition, through Raman analysis, a study can show that high temperature (˜650° C.) can potentially transform poor crystalline quality of the as-porosified Ge into quasi-monocrystalline Ge. Nevertheless, the surface roughness may be considered high, imposing a challenge on the epitaxial growth on sintered PGe. Regarding the solar cell device, a thin single crystal Ge NM can be grown on reorganized cylindrical pores, that enable the growth and transfer of GaAs solar cells. This approach can involve a careful and nonetheless complex fabrication based on the combination of expensive tools (deep UV-lithography and reactive ion etching) to obtain a regular array of uniform pores, and may be deemed too expensive to be applied for a lower-cost solar-cell application.

From the point of view of scalability and processing cost, electrochemical porosification is thus perhaps one of the most appealing pathways for lift-off and substrate re-use with appreciable levels of complexity. In the discussion below, three facts may be of particular interest: (i) demonstration of high quality 4-inch single crystal Ge on PGe by molecular beam epitaxy (MBE); (ii) detailed microstructural investigations of the epitaxial Ge layer; and (iii) assessment of the mechanical, morphological and structural properties of Ge (NM).

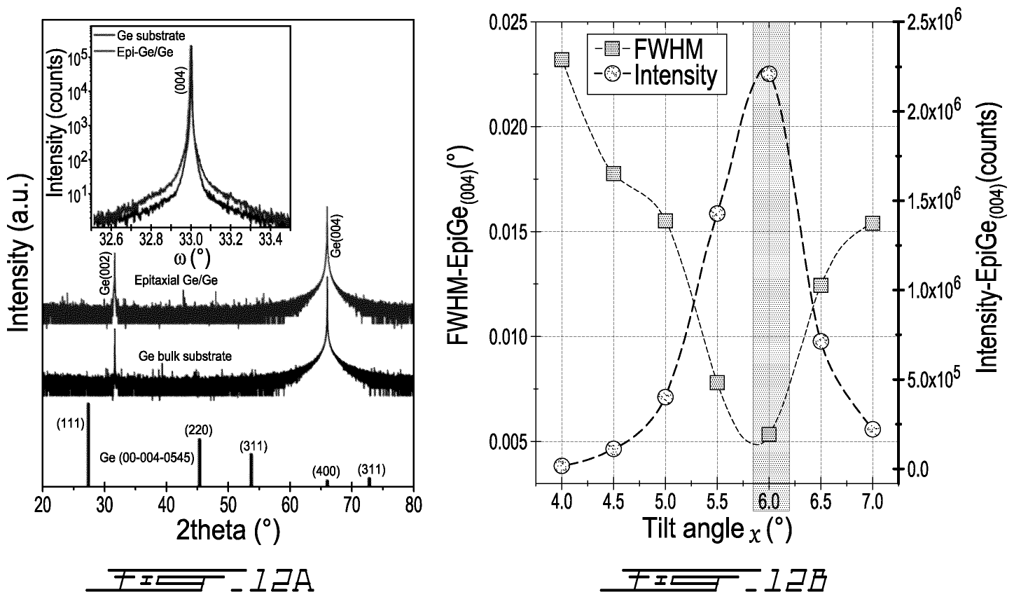

FIG. 9 illustrates an example embodiment where a sequence of steps which can be used to obtain Ge NM in the context of such a logic.

The first step is the formation of the single porous layer on 4-inch Ge substrate, with a porosity of 40-45%. After chemical cleaning, an annealing at low temperature followed by a low temperature Ge deposition is carried out to create a template for the Ge epitaxy. The third step is the annealing at high temperature to reorganize the porous structure to obtain a separation layer or weak layer. This annealing is followed by the Ge epitaxial growth at high temperature. The last step is the detachment of the structure by pull test.

Germanium substrate used (provided by Umicore®) were 180 um thick, P-doped (Ga-doped) and (001) orientation with 6° off-cut. They were anodically porosified by bipolar electrochemical etching (BEE) with a Biological SP-50® generator and with a custom-made 4 inches electrochemical cell. Before the etching, wafers were cleaned for 5 min in Ethanol and 5 min in HF. The electrolyte used was a HF:Ethanol (4:1) solution. A 30 s initialization (2.5 mA/cm⁻²) was applied before the anodization step (0.5 mA/cm⁻²-1 s pulse) and passivation step (1 mA/cm⁻²-1 s pulse).

Surface preparation was realized by deoxidation with HBr (49%): Ethanol solution and rinsing with IPA, followed by an annealing at low temperature. This annealing was performed at ultra high vacuum (˜10⁻⁶ Torr) and at 300° C. during 30 min.

Ge epitaxial structure were grown on a porous Ge substrate with a VG Semicon V90F 4-inch CBE (Chemical Beam Epitaxy) reactor for III-V materials with a liquid nitrogen cryopanel. For the propose of the growth, CBE reactor was modified to work in MBE (Molecular Beam Epitaxy) conditions. The Ge source used is a Ge Kell (heated at 1250° C.) and the pressure inside the chamber, was around 5×10⁻⁶ Torr. The growth rate was around 300 nm/h. The Ge buffer deposition were carried out at 200° C. and the epitaxial growth at 475° C.

Cross-section images was carried out using scanning electron microscopy (LEO 1540 XB®) to observe the porous structure after reorganization. An acceleration tension of 20 keV was used. The surface roughness of the porous layer as well as the epi-layer was estimated by atomic force microscopy (AFM) with a Veeco Dimension 3000® in tapping mode, with a scan rate of 0.3 Hz. The Crystalline quality of the Ge epi-layer was evaluated by using X-ray diffractometer (SMARTLAB, Rigaku) equipped with monochromated Cu—K_{α1} source (λ=0.15406 nm). The crystalline phase of the epi-layer was also studied by Raman spectroscopy was carried out using a Raman spectrometer equipped with a CCD detector and a laser with an excitation wavelength of 632 nm to analyze the epitaxial layers at room temperature. To analyse the crystalline quality, HR-TEM (Talos 200X®). The adhesion force of the epi-layer was determined from the Pull-test measurement performed using TAXT machine.

The photo in the FIG. 10(a) presents a visual inspection of the 4-inch Ge epi-layer fabricated at 3IT-Sherbrooke University and shows a mirror-like surface. To reveal the surface quality, an AFM surface analysis has been made. FIG. 10 (b) shows a smooth surface with low root mean square (RMS) roughness of 0.48 nm comparable with that of Ge substrate (RMS-0.2 nm).

FIGS. 10(c) and 10(d) show respectively the cross-sectional view of porous Ge (PGe) morphology and the epitaxial Ge layer grown on PGe/Ge bulk. It is clearly seen that the obtained porous layer had a sponge-like morphology with a thickness of ˜200 nm, porosity˜40% and a RMS of ˜2 nm. Thanks to these properties, the PGe can serve as an excellent template for the epitaxial growth of Ge layer. From the FIG. 10(d), the thickness of the Ge film is ˜700 nm, consisted of deposition of Ge buffer layer at LT (200 nm-thick) followed by the growth of HT epitaxial layer (500 nm-thick). As can be seen in the FIG. 10(d), a significant change has occurred in the morphology of the PGe during the epitaxial growth (i.e: after in-situ annealing step). Indeed, the pores tend to coalese on the top surface of the PGe and a few large voids appear at the interface of PGe/Ge substrate, which forms the so-called separation layer. This reorganization phenomenon is based on the Ostwald ripening and Rayleigh phenomenon. Indeed, the shape transformation of PGe into a voided region was largely observed for several porous structures such as, PSi, Porous InP and Porous GaN. The inset on the top of FIG. 10(d) depicts a zoom into the void region area marked by a white rectangle. The thickness of the separation layer is about −40 nm, connecting the substrate and the epi-layer through nano-bridges, which are mechanically weak, thus enabling the lift-off of the Ge NM from the reusable substrate.

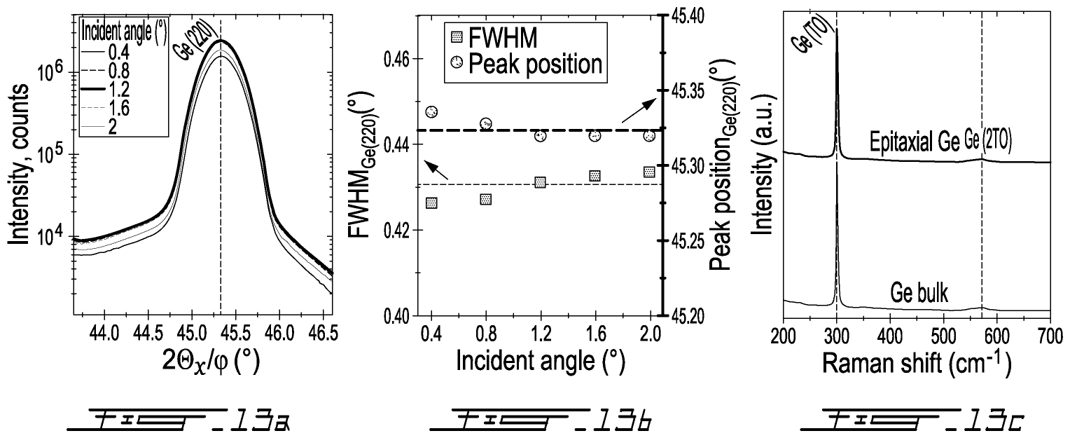

In an effort to further understand the formation of the weak layer, numerical model was developed. The reorganisation of the pore structure was confirmed by a Kinetic Monte-Carlo model which was developed in our team and subsequently improved. (REF) This model is based on the probability of diffusion and migration of Ge atoms to vacant neighbouring sites. For computational speed purposes, the scales have been modified. In normal circumstances, 1 pixel corresponds to 0.25 nm if 1 pixel corresponds to a Ge atom. In our simulation, 1 pixel corresponds to 1.25 nm. The annealing time corresponds to a given number of atomic migrations and in the case of the simulation, there were 1.5*10¹⁰ atomic jumps. FIG. 11 shows the simulation of the annealing at high temperature (600° C.), after the deposition of the low temperature buffer layer on porous structure with a porosity between 40-45% and a thickness of 180 nm.

FIG. 11 shows the representations of the porous structure at different steps of the porous transformation during the annealing at high temperature. As shown in FIGS. 10(b) and (c), the annealing will cause a morphological reorganisation which is described by the Ostwald ripening phenomenon. With annealing, the pore size change to form a weak layer with large cavities, separated by pillars (see FIG. 11(c)). In the simulation, the dimension of the pillar is around 60 nm×24 nm and in the SEM image, the average dimension of pillars is around 60 nm×35 nm. The simulation values are close to those obtained after growth. Also, at the surface of the Ge LT buffer, after annealing, some islands can be observed.

FIG. 11(b) shows the formation of the separation layer and a surface roughness on the Ge buffer. With the simulation, the height of the separation layer is close to 70 nm. This value is close to the one observed on SEM image (60 nm). The width of the pillar in the simulation is around 24 nm and 35 nm (on average) in SEM image.

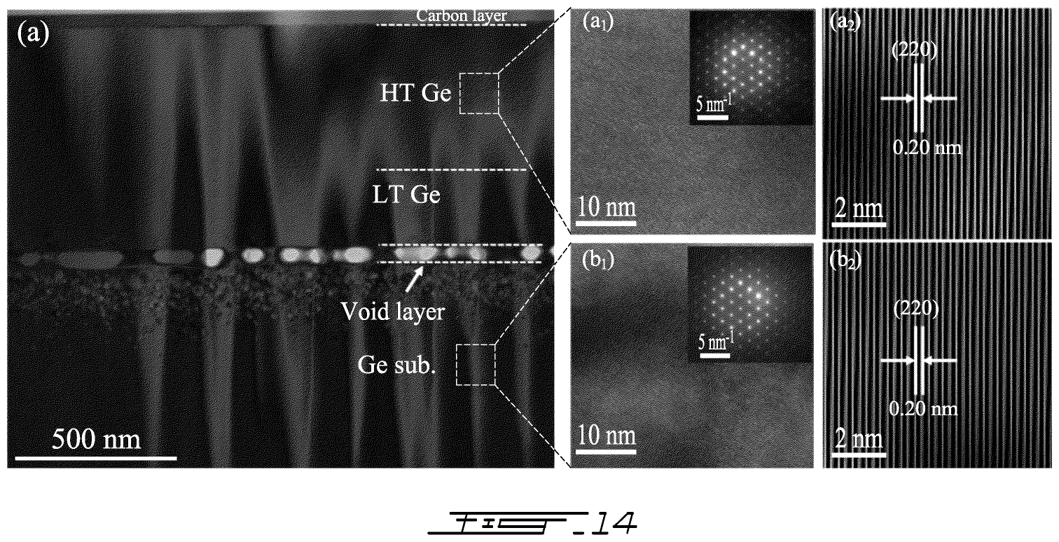

In order to study the crystallographic orientation of the epi-layers, X-ray diffraction (XRD) measurements were performed. FIG. 12(a) shows the XRD results from the 2θ-ω scan for a 700 nm thick Ge thin film grown on sintered PGe/Ge bulk. For comparison purposes, the standard XRD peaks of Ge powder and Ge bulk substrate with their corresponding crystallographic plans (JCPDS card no 04-0545) are also depicted in FIG. 12(a). The diffraction peaks observed around 2θ=31.58° and 2θ=65.98° were assigned respectively to (002) and (004) reflections of Ge. This diffraction pattern matches perfectly with the Ge cubic structure, demonstrating a strong growth orientation along with respect to the reference bulk substrate. Furthermore, no other crystalline orientations could be seen in long-range scans, refuting he presence of any polycrystalline or amorphous domains and proving thereby a highly (00I)-oriented single-crystalline nature of the grown Ge layer. It is interesting to note, that the obtained crystalline properties of p-type Monocrystalline-Ge (mc-Ge) are uniquely relevant for solar cells applications compared to the polycrystalline Ge structure. The inset of FIG. 12(a) shows the out-of-plane X-ray rocking curves (XRC) of the Ge (004) reflection of epi-Ge and Ge substrate. The XRC of the epi-Ge exhibits a narrow symmetric shape, which is a good indication of high structural quality.

The full width at half-maximum (FWHM) of the (004) peak was estimated to be about 0.0045° (16.2 arcsec), which is almost consistent with the value of 0.0041° (14.8 arcsec) expected for Ge bulk substrate measured under the same conditions. It should further be noted that the narrowest RC FWHM observed can be considered excellent for homoepitaxial Ge. For instance, Bosi et al reported a reduction of mosaic spread from 21 to 18 arcsec when increasing the growth temperature from 500° C. to 700° C. for MOVPE-Ge grown on (001) oriented Ge bulk (6° off), revealing an improvement of epitaxy upon annealing. However, in a similar work, they reported a worst crystal quality of EpiGe grown on 6° off-cut substrate compared to the exactly oriented (001) Ge one. Nevertheless, it is worth underscoring that because of the very scarce literature on the subject of homoepitaxial Ge, the RC FWHMs comparison is performed here simply on the basis of where the reported epilayers Ge were gown only on Ge bulk substrate. To the best of our knowledge, there is still no report on the crystalline quality evaluation by HRXRD of the epi-Ge grown on porous-Ge template.

To elucidate whether the 6° off-cut of the epi-Ge is preserved or not, we performed further analysis by HRXRD. For that, an original approach was adopted, based on (i) tilting the sample about the χ axis (plane of the sample rotated with respect to the incoming beam). over a wide angle range from 4 to 7°, in a way that cover the studied off-cut angle value (6°), and (ii) systematically determine the FWHM and the intensity of the main peak Ge (004) from a ω-2θ curves (not shown) at each tilt angle. FIG. 12(b) depicts the crystalline parameters variation, such as: FWHM and intensity of Ge (004) reflection as function of the χ angle. As can be seen, they are both sensitive to the tilt angle. Two opposite, but nonetheless consistent, tendencies are observed as χ is increased from 4 to 6°. In fact, the FWHM Ge(004) is found to drop markedly by almost 4.5 times from 0.023° to reach a minimum value of 0.005° when χ is increased from 4 to 6°. On the other hand, the intensity Ge(004) shows an opposite trend and was significantly increased by more than two order of magnitudes (from 1.6×10⁴ to 2.2×10⁶ counts). This can likely be explained by the existence of an narrow window that offer the best conditions (i.e 6° tilt) for the collection of diffracted crystalline planes (004). Ultimately, when χ is further increased to 7°, the FWHM Ge(004) is found to broaden from 0.005 to 0.015°, while the intensity Ge(004) was progressively drops down to a value of 2.2×10⁴ counts. The significant decrease in the intensity Ge(004) and the abrupt increase in FWHM Ge(004) with increasing χ to 7 is not surprising, since tiling the sample during the measurement beyond its off-cut angle value)(χ>6° would certainly hinder the collection of the diffracted (004) reflections. Accordingly, all these above-discussed results point out the χ=6° as the optimum tilt angle that yields the narrowest FWHM and the highest peak intensity. This leads us to conclude that the 6° off-cut is maintained during the whole growth process of Ge (i.e: porosification step, in-situ annealing and epitaxial growth). Besides, it is worth recalling that the achievement of epitaxially Ge grown films, presenting a given single crystalline phase with high degrees of orientation, and a preserved 6° off-cut could be relevant for the subsequent growth of single domain III-V compound semiconductors (i.e GaAs).

On the other hand, since the previous HRXRD study allowed us to study the quality of the epi-Ge in the out of plane direction (crystallographic planes parallel to the surface), an in-plane grazing incidence diffraction (IPGID) measurements are conducted to evaluate the structural quality in the in-plane direction (crystallographic planes perpendicular to the surface). In IPGID experiments, the X-ray penetration depth (L) is determined by the incidence angle (α), thus allowing a precise investigation of the crystalline structure at different depths. The calculation of L with the IPGID can be found elsewhere. Indeed, by scanning 2θχ and φ angles in grazing incidence (φ corresponds to the rotation of the sample on itself, while 2ex is the sample in-plane angle between the crystallographic planes and the detection), a mosaic spread can be evaluated. This 2θχ/φ in-plane configuration corresponds to a 2θ/ω configuration for crystallographic planes parallel to the surface. FIG. 13(a) shows the result of IP-GID investigations of the (220) planes of the Ge epilayer performed at different αᵢ, varied over a large range from 0.5 to 2° and corresponding to a probed thickness from 100 to 500 nm. The Ge bulk position is denoted by dotted line. As a first observation, it can be clearly seen that the diffracted pattern peak intensity remains almost unchanged regardless of the L. FIG. 5b summarizes the peak position and the FWHM variation of Ge (220) reflection as a function of αᵢ. One may notice that the values of FWHM are nearly constant and the position of (220) peak does not significantly shifts with respect of the Ge bulk. Interestingly, by looking at the probed thickness corresponding to the incident angle αᵢ, found that αᵢ.=2° corresponds to a L˜500 nm, which is perfectly coincides with the H.T Ge/L.T buffer layer Ge interface region. In addition, since the FWHM and the peak position seems not be varied throughout the probed thickness, it can be therefore concluded that the growth of the H.T Ge on L.T was of a good quality with almost no identified interface. Ultimately, this is an evidence of high quality sintered PGe (i.e. well reorganized, smooth surface), that was efficiently serve as a good template for the epitaxial growth.

The crystalline quality and the strain state (if any) of the epitaxial Ge layer grown on PGe/Ge substrate was further investigated by micro-Raman analysis. FIG. 5(c) compares representative Raman spectra recorded at room temperature from Ge bulk substrate (in black) and Epi-Ge layer (in bleu). The two spectra are practically identical. The spectra from the Epi-Ge films feature a sharp peak slightly shifted to lower wavenumbers at ω_{Ge}=300.66 cm⁻¹, with respect to the Ge bulk phonon mode (ω_{Ge bulk}=300.82 cm⁻¹) and a hump peak at ˜571.30 cm⁻¹. These two modes are attributed as the well-known Raman active first-order and second-order transverse optical (TO) phonon mode of crystalline Ge. The main Raman peak of the Epi-Ge was fitted by Lorentzian function and exhibits a FWHM of 3.20 cm⁻¹, which is similar to the one obtained for Ge bulk (3.10 cm⁻¹), suggesting a highly ordered film. On the other hand, the Raman analysis of the Epi-Ge did not reveal any evidence for the presence of additional modes characteristics to germanium oxides (i.e: 212 cm⁻¹, ˜261 cm⁻¹ and ˜440 cm⁻¹), or amorphous phase (TO mode at 278 cm⁻¹), in agreement with the XRD results that have revealed high-quality single-crystal Ge.

The in-plane biaxial strain in the Ge epilayer denoted by EH was estimated from the spectral shift of the Ge—Ge phonon vibration mode(Aw) relative to bulk Ge, according to the formula: Δω=−bε_{∥}. The b parameter depends on the phononic and elastic constants of the studied material. Using the reported literature value of b=415 cm⁻¹ for Ge, a tensile strain of =0.03% was deduced in the Ge-on-PGe/Ge epilayer for the observed Raman shift. Therefore, we believe that the Ge epilayer was almost stress free.

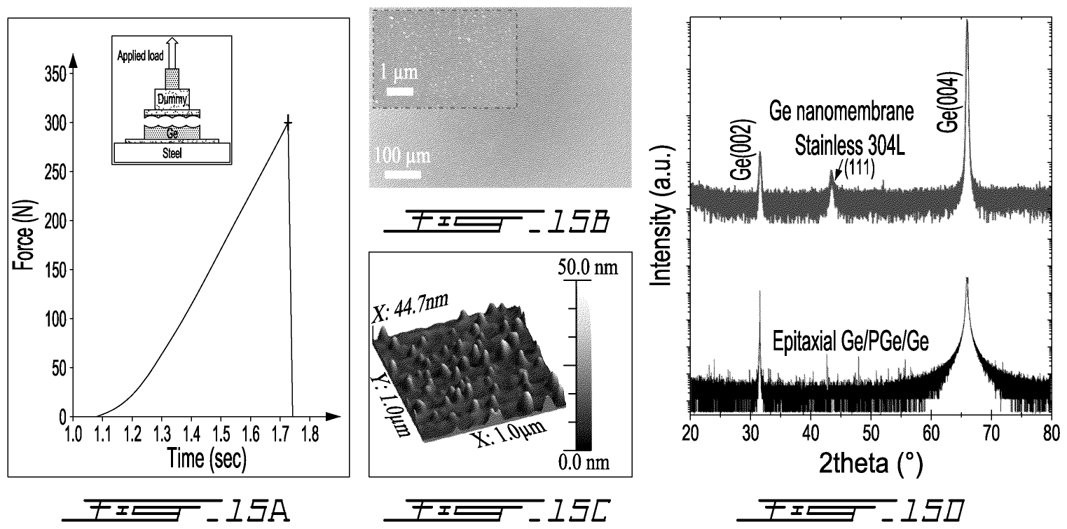

To gain more insight into the homoepitaxial layer crystal quality, the Ge epilayer was examined by high-resolution transmission electron microscopy (HRTEM). The FIG. 14(a) shows a cross section of the studied structure. The multilayered architecture is clearly distinguished into three regions: the epitaxial layer (HT+LT buffer Ge), the separation layer and the Ge bulk substrate. As expected, the TEM analysis (FIG. 14(a)) revealed a very good structural quality of the epilayer Ge. The interface between HT and LT-Ge buffer layer was continuous and largely free of defects. These observations are in accordance with the results obtained by IPGID, showing no obvious interface at H.T/L.T Ge region (at αᵢ=2°, ˜500 nm probed depth).

Further proof of the excellent crystal quality of the epilayer is visible from selected-area electron diffraction (SAED) pattern (inset a₁) obtained by applying a Fast Fourier Transform (FFT) on HR-TEM images. Indeed, SAED pattern of the epi-Ge inserted inside FIG. 14(a₁) exhibits only spotty diffraction. Moreover, there was no discernible difference with the substrate diffraction pattern (inset b₁), suggesting that a transfer of crystallographic information has taken place from the Ge substrate into the Ge epi-layer. These findings corroborate the above conclusions based on XRD measurements, thus indicate unambiguously the single crystal nature of Ge.

Fourier mask filtering tools and inverse fast Fourier transform (IFFT) were carried out to determine the interreticular distance. FIGS. 14(a₂) and 14(b₂) show respectively the generated lattice fringes for the epiGe and Ge bulk. In these figures, the lattice fringes of the (220) planes are indicated by two parallel lines. The lattice spacing is ˜0.20±0.001 nm being the same as that of Ge bulk (FIG. 14-b₂). This value is in agreement with the d₂₂₀ of the diamond cubic structure of Ge (JCPDS-04-0545). Therefore, HRTEM observations coupled with HRXRD results (out of plane and in-plane scans) collectively demonstrated the successful growth of single-crystal Ge on PGe/Ge substrates with a 6° off-cut, in a perfect cube-on-cube orientation relationship.

It is very important to emphasize that achieving such very high crystallinity has been possible because of the optimization of the porous Ge layer (i.e: surface treatment and in-situ annealing). This highlight the chief role played by the sintered PGe to be a good template for epitaxial growth while being able to ensure an efficient lift-off through the reorganized PGe region (void layer).

To confirm the viability of our approach for efficient lift-off, the epi-Ge layer was subjected to a pull-off adhesion test. The adhesion characteristic of the weak layer that connects the Ge NM with the substrate was experimentally determined for the first time, and the quality of the Ge NM has been thoroughly assessed. Firstly, the sample was glued by epoxy on a stainless steel used as a mechanical support before release. Then an external force was applied and the layer was pulled-off. Consequently, a Ge NM is successfully detached from the parent substrate and subjected to further characterization. The FIG. 15(a) depicts the Pull-test measurement. The inset shows experimental setup for measuring the adhesion force. In fact, the obtained curve can be divided into two regimes, the first one correspond to elastic regime, which is a linear part and then the fracture region. The adhesion force is estimated to be about XX N, which correspond to the required force for pillars (nano-bridges) destroying.

Top view SEM in FIG. 15(b) shows a smooth morphology, uniform and intact surface of the Ge NM, implies that the lift-off approach retains the surface quality of the film. The inset shows an homogenous distribution of the remained pillars. The AFM image (FIG. 15(c)) provides further visual verification of the quality of the surface, and reveals an RMS of ˜6 nm. It's interesting to note that the surface of Ge NM can be easily smoothed for the following epitaxial growth through appropriate chemical treatment.

The crystallinity of the Ge NM was assessed by XRD (2θ scan). FIG. 15(d) presents the XRD patterns of the Ge NM and the Stainless steel, which is considered here as a host substrate. The observed pattern of the free-standing Ge NM were associated to (002) and (004) crystalline planes similar to those of the Ge epilayer before detachment, demonstrating convincingly that the crystalline structure of the Ge NM is preserved after the detachment. Furthermore, the peak appeared at 43.77° corresponds to (111) crystalline plane of face-centered cubic structure of stainless steel (304L). This indicates therefore the successful transfer of the Ge NM on a foreign substrate. Overall, both the morphological properties and structural characteristics obtained here strongly indicate the high quality of the Ge NM. Thus, demonstrates the potential of our approach for an efficient lift-off.

As can be understood, the examples described above and illustrated are intended to be exemplary only. For instance, it is encompassed that the optoelectronic devices can be directed to solar cell applications or laser applications. The scope is indicated by the appended claims.

1. A method of making a component, said method comprising the steps of:
at a first temperature, depositing a first non-porous layer of monocrystalline germanium (Ge) onto a porous layer of a monocrystalline Ge substrate;
at a second temperature, depositing a second non-porous layer of monocrystalline Ge onto said first non-porous layer, the second temperature higher than the first temperature; and
detaching the first non-porous layer, together with the second non-porous layer, from the monocrystalline Ge substrate.

2. The method of claim 1 wherein the first temperature is below 400° C., preferably between 150 and 300° C.

3. The method of claim 1 wherein said first non-porous layer is deposited using a low temperature precursor, preferably digermane or germane.

4. The method of claim 1 wherein said first non-porous layer is deposited at a thickness between 10 and 100 nm.

5. The method of claim 1 wherein the second temperature is above 400° C.

6. The method of claim 1 wherein said second non-porous layer is deposited using a high temperature precursor, preferably germanium tetrachloride (GeCl₄).

7. The method of claim 1 wherein said first non-porous layer and said second non-porous layer have a combined thickness between 1 and 600 μm.

8. The method of claim 1 wherein said second non-porous layer has a thickness of at least an order of magnitude greater than a thickness of the first non-porous layer.

9-10. (canceled)

11. The method of claim 1 further comprising the step of depositing at least one additional layer onto said second non-porous layer, wherein said at least one additional layer includes one or more layers of III-V semiconductor crystalline materials and said component is a component of an opto-electrical device.

12. The method of claim 1 further comprising the step of annealing the first non-porous layer and the substrate at a temperature above 400° C., prior to depositing said second non-porous layer.

13. (canceled)

14. The method of claim 1 further comprising the step of forming a porous external layer of monocrystalline germanium (Ge) in a non-porous substrate of monocrystalline germanium prior to depositing said first non-porous layer.

15. The method of claim 1 whereby said first non-porous layer, together with the second non-porous layer, is detached from said porous layer of said monocrystalline Ge substrate by pulling the first layer together with the second layer off from the substrate, including yielding of said porous layer to mechanical stress imparted by the pulling.

16. The method of claim 15 wherein said yielding of said porous layers includes breaking a plurality of pillars extending between the first layer and a non-porous portion of the monocrystalline Ge substrate, a plurality of protrusions including a portion of said plurality of pillars remaining on an exposed surface of said first layer subsequently to said detaching.

17. The method of claim 1 further comprising the step of chemically cleaning an exposed face of said porous layer, prior to depositing said first non-porous layer.

18. The method of claim 17 wherein said chemically cleaning includes replacing oxidation on said exposed surface by halogen surface terminations.

19. The method of claim 17 wherein said chemical cleaning includes applying a halogen-solvent solution to the exposed surface.

20. (canceled)

21. The method of claim 17 further comprising performing a low temperature annealing of the monocrystalline Ge substrate subsequently to said chemically cleaning and prior to depositing the first non-porous layer, the low temperature annealing at a temperature of between 100 and 400° C., preferably between 200 and 300° C.

22. The method of claim 21 including moving the substrate into an oven prior to said low temperature annealing, and maintaining the substrate in the oven during the steps of performing deposition of the first non-porous layer and of performing deposition of the second non-porous layer.

23-26. (canceled)

27. A germanium wafer comprising an layer of monocrystalline GE having between 1 and 600 um between a first face and a second face, the second face being exposed and having a plurality of protrusions protruding away from the first face, the protrusions being irregularly distributed across the second face and having a depth normal to the second face of between 10 and 50 nm, and a diameter ranging from 20 nm to 500 nm.

28-29. (canceled)

30. An optoelectronic device comprising a layer of monocrystalline GE having a thickness between 1 and 600 um between a first face and a second face, one or more layers of III-V semiconductor crystalline materials layered onto the first face, the second face being exposed and having a plurality of protrusions protruding away from the first face, the protrusions being irregularly distributed across the second face and having a depth normal to the second face of between 10 and 50 nm, and a diameter ranging from 20 nm to 500 nm.

31-48. (canceled)
